(19) United States
(12) Patent Application Publication
(10) Pub. No.: US 2025/0210377 A1
(43) Pub. Date: Jun. 26, 2025

(54) LINEAR REACTOR FOR SUBSTRATE PROCESSING

(71) Applicant: Mitch Hoerner, Columbia Falls, MT (US)

(72) Inventor: Mitch Hoerner, Columbia Falls, MT (US)

(21) Appl. No.: 18/656,816

(22) Filed: May 7, 2024

Related U.S. Application Data
(60) Provisional application No. 63/613,452, filed on Dec. 21, 2023.

(51) Int. Cl. H01L 21/67

(52) U.S. Cl. CPC H01L 21/67017; H01L 21/67173

(57) ABSTRACT

A linear reactor that is capable of performing many of the semiconductor substrate processing steps in order to manufacture an integrated circuit. The linear reactor permits a number of different processing steps to take place within the reactor in the manufacture of an integrated circuit. Thus, single reactor furnaces can be used for most, and potentially all, semiconductor processing steps of an integrated circuit. The linear reactor has a chamber that extends linearly from a first end to a second end and gases flow from the first end into the second end during the semiconductor processing steps. The chamber is bounded by a top wall and the bottom wall with a space in between that provides the chamber in which the semiconductor processing steps are carried out.

### RELATED APPLICATION

The present application relates and claims priority to U.S. Provisional Application No. 63/613,452, filed on Dec. 21, 2023, which is hereby incorporated by reference in its entirety.

### TECHNICAL FIELD

The present application relates generally to systems and methods for chemical processing, including substrate processing to manufacture semiconductors and nanodevices and, more particularly, to an adaptable linear reactor framework for treating semiconductor substrates to manufacture integrated circuits thereon.

### BACKGROUND

A variety of equipment, such as furnaces, reactors, and other processing equipment (collectively “reactors”) used for the fabrication of integrated circuits from semiconductor wafers are well known in the art. Semiconductor fabrication requires numerous steps and processes, which all require immense precision. Typically, manufacturers utilize a different reactor for each fabrication step and process. Each of these reactors require different configurations specifically tailored to their precise task. For example, one reactor may be used for etching substrates while a different reactor is used for Chemical Vapor Deposition (CVD). Due to the extreme precision required for said fabrication steps, manufacturers are willing the bear the costs associated with supporting many different reactors to ensure adequate precision.

### SUMMARY OF THE INVENTION

According to principles of the present disclosure, a linear reactor is provided capable of performing many, if not all, of the semiconductor substrate processing steps needed to manufacture an integrated circuit. The linear reactor permits several different processing steps to take place within a single reactor. This may greatly reduce the number of reactors needed for all semiconductor processing steps.

The linear reactor can process and treat any substrate. In one embodiment, the substrate is a semiconductor wafer, but in other embodiments, it is other materials, such as quartz, a PCB, glass, plastic or other acceptable substrate.

The linear reactor has a chamber that extends linearly from a first end to a second with means to permit fluid flow from the first into the second end during the semiconductor processing steps. The chamber is bounded by a top wall and the bottom wall with a space in between that provides the chamber in which the semiconductor processing steps are carried out. The height of the chamber is relatively low, thus providing precise control of the fluid flow dynamics within the chamber itself.

The linear framework is designed to streamline chemical additive and subtractive steps of nanodevice manufacturing. It achieves this by providing comprehensive solutions for controlling chemical reactions across a wide range of environmental conditions. The framework offers all the necessary manufacturing needs, including substrate handling, fluid delivery, waste management, and energy activation, all within a common frame and reactor furnace. The environmental conditions that can be created and carried out within this linear reactor are so broad they include all conditions that are currently used by all other semiconductor processing equipment on the market today. The design of this linear reactor allows for the replacement of several current reactor furnaces in use today with either a single reactor that carries out all of the semiconductor processes or a small set of reactors that share a common framework, including the ability to conduct all wet and dry process applications in the manufacture integrated circuits. This consolidation of manufacturing equipment into a single reactor furnace or, potentially, two or three reactor furnaces for the entire manufacturing process from start to finish of the completed integrated circuit offers efficiency gains up and down the supply chain, promising to ease the economic and environmental burdens of nanodevice production.

Aspects of this application are directed to systems and methods for processing a substrate.

In one example, a system for processing a substrate is disclosed. The system includes a first plate defining a first surface and a second plate positioned off-set and parallel to the first plate defining a second surface, wherein the second plate is configured to receive the substrate and arrange a surface of the substrate parallel to and in-plane with the first surface or the second surface. The system further includes a reaction chamber formed between the first surface and the second surface with the second surface of the second plate within the reaction chamber. The system further includes a fluid management device, positioned at a first end of the first plate, in fluid communication with the reaction chamber, and configured to introduce fluid into the reaction chamber. The system further includes a second fluid management device, positioned at a second end of the first plate, in fluid communication with the reaction chamber, and configured to receive and/or draw fluid from the reaction chamber. The system is configured to fabricate electronic circuits onto the substrate by passing fluid over the substrate from the first hydraulic device to the second hydraulic device.

The first fluid management device may include a first hydraulic device including a first piston positioned within a first hydraulic volume. The system may include a first isolation valve operable to facilitate fluid communication between the first hydraulic device and an external fluid source and a first gate load lock positioned between and separating the first hydraulic volume and the reaction chamber. The first piston may be configured to draw the fluid from the external fluid source into the first hydraulic volume and upon closing of the first isolation valve and opening of the first gate load lock, induce a flow of the fluid into the reaction chamber.

The external fluid source may comprise a plurality of individual fluids and the first isolation valve may be a component of a manifold that selectively controls the fluid coupling of each fluid of the plurality of individual fluids to the first hydraulic device.

The first hydraulic volume may include a volume having a cross-sectional area larger than a cross-sectional area of an internal volume of the reaction chamber and the first piston may be configured to induce a constant flow of the fluid into the reaction chamber such that a velocity of the fluid increases through the reaction chamber while the mass flow rate remains constant.

A ratio of the cross-sectional area of the first hydraulic volume to the cross-sectional area of the reaction chamber may be at least 40:1.

The reaction chamber may be enclosed by an edge seal connecting the first plate to the second plate to define a linear flow path for the fluid through the reaction chamber along the first surface and second surface.

The first plate may comprise an inlet extending therethrough and fluidly coupling the hydraulic device and a first end of the reaction chamber. The first plate may further comprise an outlet extending therethrough and fluidly coupling the second hydraulic device and a second end of the reaction chamber.

The surface of the substrate may be arranged between the first and second ends of the reaction chamber.

The second plate may include a removable section including a depression configured to house the substrate such that the substrate is flush with a top surface of the second plate. The removable section may be configured to selectively place the substrate within the reaction chamber.

The first plate and/or the second plate may include at least one layer positioned within or integrally formed to the first plate and/or second plate and the at least one layer may be operable to heat and/or cool an environment of the reaction chamber.

The system may be operable to produce a uniform fluid velocity profile within the reaction chamber and across the surface of the substrate within the reaction chamber. The substrate may be a silicon wafer.

Fabrication of electronic circuits onto the substrate may comprise one or more of lithography, photoresist coating, Chemical mechanical Polishing (CMP), Physical Vapor Deposition (PVD), Chemical Vapor Deposition (CVD), diffusion, ion implantation, dry etching, tripping, and/or washing.

In another example, a system for processing a substrate is disclosed. The system may include a reactor module configured to induce a uniform flow of a process fluid across a surface of a substrate held within a linear reaction chamber. The system may further include a fluid input module fluidly coupled with the reactor module and configured to deliver a flow of the process fluid to the linear reaction chamber. The system may further include a fluid output module fluidly coupled with the reactor module and configured to receive and/or draw fluid from the linear reaction chamber. The system may further include at least one support module thermally and fluidly coupled with the reactor module and configured to control a temperature of the reaction chamber, a pressure of the reaction chamber, and/or a flow rate of the fluid. The system may further include at least one side module electrically coupled with the reactor module and configured to provide an electric current to the fluid and/or an electric field to the reaction chamber. The reactor module, the fluid input module, the fluid output module, the at least one support module, and the at least one side module may cooperate to fabricate electronic circuits onto the substrate within the linear reaction chamber.

The reactor module, the fluid input module, the fluid output module, and the at least one support module may define a modular framework whereby the modular framework is configured to facilitate removable attachment of the fluid input module, the fluid output module, the at least one support module, and/or the at least one side module to and from the reactor module.

The system may further comprise at least one substrate handling module configured to introduce a substrate to the reaction chamber and the modular framework may include the at least one substrate handling module.

In yet another example, a method for processing a substrate is disclosed. The method may include selecting a process fluid from an external fluid source. Then, isolating the process fluid from the external fluid source from and fluidly coupling the process fluid to a reaction chamber. Next, a uniform flow of process fluid may be induced through the reaction chamber by generating pressure at an inlet of the reaction chamber causing flow of the process fluid into the reaction chamber. Followed by, drawing the fluid from the reaction chamber by generating pressure at an outlet of the reaction chamber opposite the inlet. Finally, fabricating electronic circuits onto the substrate by passing the uniform flow of process fluid over the substrate positioned within the reaction chamber.

The method may further comprise applying an electric current to the uniform flow of process fluid by at least one electrode electrically coupled with the reaction chamber.

Fabricating electronic circuits onto the substrate may comprise one or more of lithography, Chemical mechanical Polishing (CMP), Physical Vapor Deposition (PVD), dry etching, and/or washing.

### BRIEF DESCRIPTION OF THE DRAWINGS

FIG. 1 illustrates an isometric view of an example linear reactor system.

FIG. 2A illustrates a semi-transparent isometric view of an example linear reactor system with a substrate placed therein.

FIG. 2B illustrates a magnified view of the linear reactor of the example linear reactor system of FIG. 2A.

FIG. 3A illustrates the reaction chamber of the linear reactor system of the present disclosure.

FIG. 3B illustrates the convection forces at play within the reaction chamber of the linear reactor system of FIG. 3A.

FIG. 3C illustrates the reaction chamber of a prior art reactor.

FIG. 3D illustrates the convection forces at play within the reaction chamber of the prior art reactor of FIG. 3C.

FIG. 4A illustrates an example linear reactor with a sealed reaction chamber.

FIG. 4B illustrates the reaction chamber of the example linear reactor of FIG. 4A.

FIG. 4C illustrates an example linear reactor system with a sealed reaction chamber.

FIG. 4D illustrates the reaction chamber of the example linear reactor of FIG. 4C.

FIG. 5 illustrates an example linear reactor system with a removable section for substrate placement.

FIG. 6A illustrates an example fluid management system.

FIG. 6B illustrates another example fluid management system.

FIG. 6C illustrates another example fluid management system.

FIG. 6D illustrates another example fluid management system.

FIG. 7 illustrates a schematic diagram of an example fluid delivery system to the linear reactor system.

FIG. 8 illustrates an isometric view of an example fluid delivery system to the linear reactor system.

FIG. 9 illustrates a cross-sectional view of an example fluid input module to the linear reactor system.

FIG. 10 illustrates a cross-sectional view of the example fluid input module of FIG. 9 as fluid is delivered to the linear reactor system.

FIG. 11A illustrates a cross-sectional view an example linear reactor system prior to fluid delivery.

FIG. 11B illustrates a cross-sectional view of the example linear reactor system of FIG. 11A during fluid delivery.

FIG. 12 illustrates a schematic of an example fluid delivery system of the linear reactor system.

FIG. 13 illustrates a block diagram schematic of an example linear reactor framework.

FIG. 14A illustrates an example configuration of the linear reactor system.

FIG. 14B illustrates another example configuration of the linear reactor system.

FIG. 15A illustrates an example plate module of the linear reactor system.

FIG. 15B illustrates a magnified view of an example configuration of the functional layers of the example plate module of FIG. 14A.

FIG. 16 illustrates a cross-sectional side view of an example configuration of the linear reactor framework with heating and cooling components.

FIG. 17 illustrates a cross-sectional side view of the linear reactor system with pressure control components.

FIG. 18 illustrates a cross-sectional side view of an example linear reactor framework configured for chemical free processing.

FIG. 19 illustrates a top-down view of a linear reactor configured for atomic layer deposition.

FIG. 20 illustrates a cross-sectional side view of the linear reactor of FIG. 19.

FIG. 21 illustrates a cross-sectional side view of a linear reactor configured for ion implantation.

FIG. 22 illustrates a cross-sectional side view of a linear reactor configured for ion etching.

FIG. 23 illustrates a cross-sectional side view of a linear reactor configured for electroplating.

FIG. 24A illustrates a cross-sectional side view of a linear reactor configured for photolithographic patterning.

FIG. 24B illustrates a cross-sectional side view of the linear reactor of FIG. 24A following photolithographic patterning.

FIG. 25 illustrates a side-view of an example linear reactor configured for reel-to-reel processing of flexible film materials.

FIG. 26 illustrates a side view of an example linear reactor configured for mechanical pressing of solid films onto substrates.

FIG. 27 illustrates a flow diagram of a method for processing a substrate.

### DETAILED DESCRIPTION

The outcome of chemical processing is determined by the material inputs and the environmental conditions in which they react. Chemical processing often requires very tight control over the process's environmental conditions to ensure the desired outcome. The linear reactor framework allows for very tight control over all variables that determine the formation and destruction of chemical bonds. The framework is adaptable to react fluids with any other material regardless of the phase: solid, liquid, and gas (vapor). This technology may be adopted in many industries where chemical processing is required. This includes the Semiconductor Industry, where nanodevices are created using additive and subtractive chemical manufacturing techniques. These same techniques can be used in many other industries to precisely control the outcome of chemical reactions.

The fabrication of electronic circuits onto substrates to create semiconductors and nanodevices can be a tedious process requiring extreme levels of precision and numerous different and distinct manufacturing steps. However, this is required to create modern electronic devices. For example, a single semiconductor may require many chemical additive and subtractive process steps including wet process, cleans, surface passivation, photolithography, ion implantation, etching, Chemical Vapor Deposition (CVD), Atomic Layer Deposition (ALD), Physical Vapor Deposition (PVD), a variety of thermal treatments, die preparation, and Integrated Circuit (IC) packaging. Typically, Integrated Device Manufacturers (IDMs) employee a wide variety of equipment to effectuate these process and fabrication steps. Due to the extreme level of precision required, equipment and reactors are specifically configured to accomplish one or a select few fabricating steps. Due to the high level of precision needed, equipment is statically configured for their specific task. Modularity of said equipment can be expensive, time consuming, and potentially ineffective.

Today's electronic devices function due to their designed electrical characteristics. However, particle defects that occur during the manufacturing process can alter these properties and cause malfunction. Particle defects are any self-contained combination of solid matter that can be moved in a fluid or by a charge. For example, the main sources of particle defects include friction between solid surfaces, flaking, chemical compatibility, friction between fluid and solid surfaces, static discharge sparks, and reaction build-up. For successful nanodevice manufacturing, the fundamental forces that move particles onto a substrate surface must be understood and practically applied. This means managing the fluids and charges in the system that can move and transport particle defects.

Due to the plethora of equipment and reactors needed by any single IDM, there is a large monetary and spacious requirement for semiconductor fabrication. Given the immense need for modern electronic devices, manufacturers are willing to bear the costs associated with said requirements. However, there is ample space for improvement in this field. Namely, by reducing the sheer number of distinct and unrelated reactors and establishing a higher degree of standardization between all types of chemical processing equipment needed to completely fabricate semiconductors. One way this may be accomplished is by increasing the modularity (i.e., the standardization adaptability) of a reactor so that it can support more than one manufacturing technique. Additionally, reactors can be manufactured to be more commodious. The present application is directed to a system that provides such improvements. The system of the present application is a linear reactor system and linear reactor framework operable to produce a flow of fluid with uniform and programable convection characteristics through a reaction chamber to process a substrate placed therein needed to effectuate the variety of manufacturing techniques. The linear reactor framework provides an adaptable framework or scaffolding that enables the linear reactor to be furnished with a variety of removable components to further effectuate the variety of manufacturing techniques. As used herein, the linear reactor refers to the primary central component housing the reaction chamber for substrate processing. The linear reactor framework refers to a modular system including the linear reactor enabling the addition of configurable modules to affect an environment of the reaction chamber to control chemical bonds and affect properties of fluid used to process the substrate.

Furthermore, the present invention is directed towards addressing defect sources. Defect sources can only be minimized in practice but not eliminated completely. However, the linear reactor framework provides advanced defect management. The framework's characteristics remove dead zones and enable uniform, predictable, programable forces for defect removal and management. During maintenance, these forces can be substantially above the chemical processing conditions to remove at-risk particle defects. This ensures remaining defects during chemical processing are low-risk and unlikely to contribute to defects. In addition, the framework allows for integrated solutions like in-line filtering post valves and mechanical devices and alternate fluid paths. This approach to defect management contributes to higher uptime, lower manual maintenance, and lower cost of ownership for end users.

The linear reactor framework is designed to streamline the requirements of chemical additive and subtractive manufacturing of semiconductors and other nanodevices, as well as maintenance and defect control. It achieves this by providing modular components for controlling chemical reactions across a wide range of environmental conditions. The linear reactor framework offers the ability to standardize all the necessary manufacturing needs, including substrate handling, fluid delivery, waste management, and energy activation, all within a common framework. The environmental features operable to be produced by the linear reactor framework are broad enough to encompass the combined conditions of other chemical processing equipment used by IDMs. The linear reactor framework essentially consolidates the manufacturing equipment and methods needed in the field, which may greatly reduce the financial burden and spatial requirement for fabricating semiconductors and nanodevices.

The linear reactor is generally designed with a rectangular and flat configuration to allow fluid to be managed from side-to-side. The linear reactor may comprise a reaction chamber formed between two rectangular flat plates positioned between at least one fluid management system or device. The reaction chamber may be formed by an adjustable gap between two plates where the substrate may be placed and processed. The fluid management system may be operable to induce a flow of fluid through the reaction chamber, flowing from one end of the linear reactor to another (i.e., along the length of the rectangular shape). The reaction chamber may be adjustably configured to fit any flat substrate, such as a silicon wafer. Additionally, the reaction chamber can further be configured to accommodate any wafer size. The substrate may be placed such that it is in plane with an interior surface of the reaction chamber walls. The linear reactor receives a substrate on a wall of the reaction chamber, such that it lay flat and is flush against the reactor wall. This allows fluid (i.e., gas, liquid, or plasma) to flow over the substrate uniformly and without disruption to the established or evolving convection profile as the fluid moves throughout the reaction chamber. This enables an operator to precisely control the fluid motion characteristics, as once an initial fluid motion is established as useful, it can be repeated reliably within the reaction chamber. The flow of fluid induced into the reaction chamber may be constant, pulsed, or tapered.

Fluid convection uniformity is achieved by utilizing at least one fluid management system that induces a flow of fluid through the thin gap of the reaction chamber. The fluid management system may induce the fluid flow by creating a pressure differential between at least two fluid management modules or devices. The fluid management system may include a variety of different mechanism for inducing the flow of fluid. The reaction chamber may be configured to have a very thin gap for the fluid to flow through. This restricts the fluid motion in the z-direction, resisting the convection forces at play within the reactor cross-section. Additionally, by placing the substrate within the walls of the reactor, such that it is flush with one or both plates, the fluid motion remains undisturbed as it continues through the reaction chamber channel. This applies for gas, plasma, and liquid phase media. Manufacturers are enabled to utilize forced convention without relying on typic more variable free convention and long-distance diffusion forces present in modern vacuum processes.

The linear reactor may be included in a linear reactor framework operable to support several support modules. The linear reactor framework includes the reaction chamber formed within the linear reactor, which may be centered around said framework to receive a plurality of supporting modules. The supporting modules may be included to affect an environment of the reaction chamber and affect properties of the fluid media. The framework may function as a scaffolding configured such that the plurality of supporting modules may be positioned above, below, on any side, or at an angle of the framework relative to the reaction chamber. For example, the reactor framework may include means to support passive fluid distribution, primary pressure regulation, secondary pressure regulation, direct drive pressure regulation, filtration, thermal control, ionization, electrodes, sonic energy, condensation, and vapor generation. The linear reactor framework enables control of temperature, pressure, flow rate, and activation of incoming or outgoing fluid within the reaction chamber. The linear reactor framework is operable to include certain supporting modules while excluding others depending on the process requirement.

The linear reactor may further be equipped with energy input modules operable for activation and ionization of energy inputs close to the substrate. The modules may be configurable to affect certain areas of the substrate or provide uniform activation reactions. The energy input modules may be configured to facilitate or encourage a chemical reaction by providing the required energy to make the reaction favorable. For example, the energy input modules may support modules for emitting Infrared (IR) heating or cooling, Ultraviolet (UV), visible, microwave, Radiofrequency (RF), sonic, or nuclear radiation into the reaction chamber.

The linear reactor framework may be configured to facilitate a wide variety of nanodevice manufacturing steps in order to process a substrate. For example, the linear reactor may include supporting modules to effectuate deposition, photoresist coating, lithography, etching, ion implantation, or other manufacturing steps not specifically listed herein. The linear reactor framework is capable of effectuating said processes through the modularity provided by the framework. By providing a reaction chamber fluidly connected to at least one fluid management device operable to induce a uniform fluid flow with a supportive framework operable to provide modules to affect the environment of the reaction chamber, the linear reactor framework supports all manufacturing techniques and nanodevice fabrication steps necessary to support semiconductor creation.

### Linear Reactor

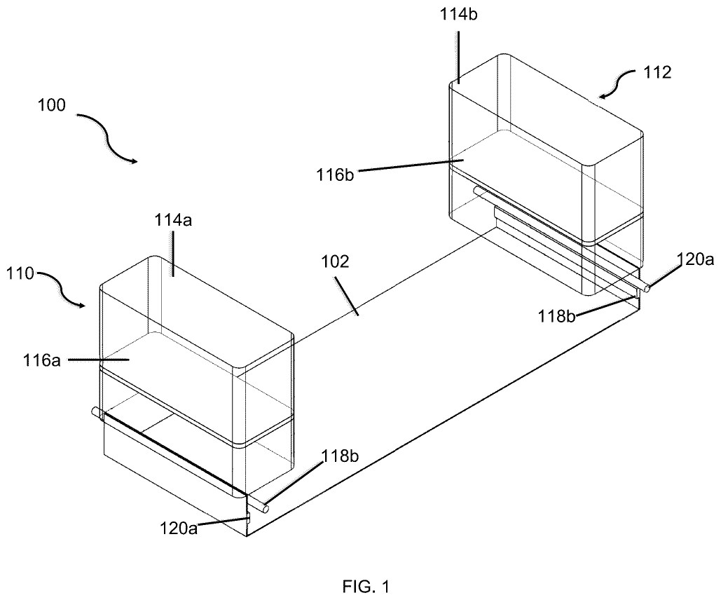

FIG. 1 illustrates an isometric view of an example linear reactor system 100. The linear reactor system 100 is depicted and described herein to illustrate an example configuration of the linear reactor with example components to effectuate one of the many processes supported by the system. Accordingly, while the linear reactor system 100 may be described as being configured for a particular process, it will be appreciated that a variety of configurations and modular components may be used to effectuate different steps necessary to fabricate electronic components onto substrates for semiconductors and nanodevices manufacture. For illustrative purposes, the following discussion may describe the linear reactor system 100 as having specific components that may only be applicable for a particular configuration (i.e., to effectuate a manufacturing step). However, one of ordinary skill in the art will understand that the linear reactor system 100 may be configured with one, many, and/or all the described components and modules. Additionally, one of ordinary skill in the art will appreciate that any one figure should not be construed as limiting, but as exemplary to the adaptability of the linear reactor system.

Generally, the linear reactor system includes a linear reactor housing the reaction chamber, configured to receive a substrate, positioned between fluid management devices. With reference to the example linear reactor system 100 of FIG. 1, the example linear reactor system 100 may comprise a linear reactor 102 positioned between a fluid input module 110 and a fluid output module 112 (collectively “fluid management devices,” functioning as a fluid management system, and referenced as such). Each fluid module or fluid management device (i.e., fluid input module 110 and fluid output module 112) may include a fluid volume (114a, 114b), a piston (116a, 116b), a fluid manifold (118a, 118b), and/or a gate load lock (120a, 120b). The fluid management system may be operable to select a specific media to be induced into the reaction chamber of the linear reactor 102. The linear reactor 102 may include a substrate (not illustrated) positioned therein, such that as fluid is passed from the fluid input module 110, through the reactor 102, and to the fluid output module, the fluid passes over the substrate and the substrate is processed.

The substrate may comprise a silicon wafer or any other thin film used for semiconductor device fabrication known in the art. The substrate may also comprise any other flat solid material capable of supporting additive and subtractive chemical processing techniques. Processing the substrate may comprise a variety of chemical additive or subtractive manufacturing methods. For example, processing may comprise deposition techniques, such as Physical Vapor Deposition (PVD), Chemical Vapor Deposition (CVD), Electrochemical Deposition (ECD), Molecular Beam Epitaxy (MBE), Atomic Layer Deposition (ALD), or any deposition technique known in the art. As another example, processing may comprise removal techniques, such as wet etching, dry etching, or Chemical-Mechanical Planarization (CMP). As another example, processing may comprise patterning techniques, such as photolithography. As another example, processing may comprise modification of electrical properties of the substrate by ion implantation or furnace annealing.

Generally, the fluid input module 110 is operable to initially drawn in fluid to the fluid volume 114, through the fluid manifold 118 while the gate load lock 120 is in a closed position, isolating the reactor 102 from the fluid. In order to induce a uniform flow of fluid into the reaction chamber of the linear reactor 102, the fluid management system creates a pressure differential between the fluid input module 110 and fluid output module 112 and the gate load lock 120 is opened. The pressure differential may be created by the fluid management system. For example, through hydraulic force by the piston 116a of the fluid input module 110 applying an inducing force equal to or substantial equal to a drawing force applied by the piston 116b of the fluid output module 112.

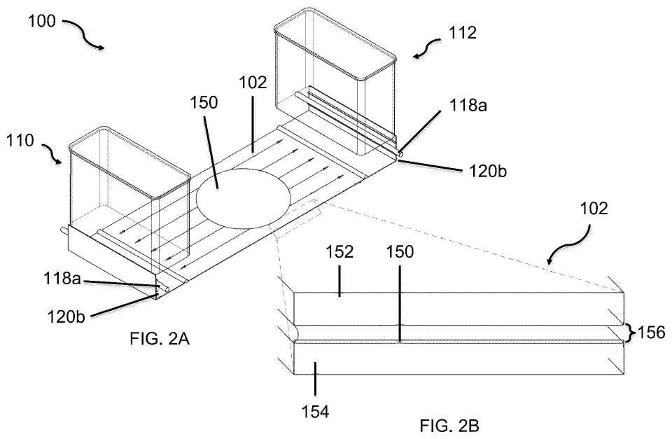

FIG. 2A illustrates the example linear reactor system 100 with a substrate 150 placed therein and FIG. 2B illustrates a magnified view of the linear reactor 102 of the example linear reactor system 100 of FIG. 2A. The purpose of FIG. 2B is to illustrate the internal components of the reactor 102 and how the substrate is placed therein. For illustrative purposes, FIG. 2A includes a transparent portion, such that the substrate 150 is visible.

With reference to the example linear reactor system 100 of FIG. 2A, the example linear reactor system 100 may be substantially analogous to the example linear reactor system 100 of FIG. 1 and may include: a fluid input module 110, a fluid output module 112, a reactor 102, fluid manifolds (118a, 118b), and gate load locks (120a, 120b). The example linear reactor system 100 of FIG. 2A may also include a substrate 150 placed within the reactor 102.

With reference to the reactor 102 of FIG. 2B, the reactor system 102 may generally comprise a first plate 152, a second plate 154, a reaction chamber 156 formed therebetween, and a substrate 150 positioned therein. The reaction chamber 156 is formed by an adjustable gap formed between the first and second plates (152, 154). The first and second plates (152, 154) may be parallel and offset to create an internal volume between them. The first plate 152 and the second plate 154, in conjunction with the remaining components of the present disclosure, create a volume that forms the reaction chamber 156 for processing the substrate 150.

As illustrated in FIG. 2A, a fluid may be induced into the reaction chamber 156 and passed over the substrate 150 to process the substrate 150. The fluid management system, comprising the fluid input module 110 and the fluid output module 112 (sometimes referred to as “fluid management devices”), may be positioned at ends of the linear reactor system 102, be in fluid communication with the reaction chamber 156, and be configured to introduce fluid to and draw fluid from the reaction chamber 156. The fluid management system may be operable to induce the flow of fluid over the substrate 150 by causing the fluid to move from one end of the linear reactor 102 to another. The substrate 150 may be processed by contact and reaction with the fluid. For example, the linear reactor system 100 may be configured to include electrodes or other hardware components operable to apply energy to the fluid entering the reaction chamber 156 to create a plasma. When the activated fluid is passed over the substrate 150, it can be used to perform a number of semiconductor processing techniques, including etching, chemical vapor deposition (CVD), introducing dopants into the substrate, growing or depositing layers thereon, for example, growing in oxide, depositing the a nitride layer, and depositing various insulating layers, such as silicon dioxide, silica nitride or various conductive layers, including doped polysilicon, titanium, aluminum, nickel, or any of the metal layers used in semiconductor processing. The activated fluid (e.g., plasma) may also be used for annealing, cleaning, or any number of the many process steps used in integrated circuit formation of a semiconductor substrate.

As illustrated in FIG. 2B, the substrate 150 is positioned within the reaction chamber 156 such that a top surface of the substrate 150 is flush with a top surface of the second plate 154. The second plate 154 may include means to accommodate the substrate 150. For example, the second plate 154 may include a depression, a removable section to accommodate the substrate 150, or a combination of both. As another example, the substrate may be configured to span the entire length and width of the second plate 154. The substrate may also be positioned on or within the first rigid plate 152 in a substantially similar way to that of the second rigid plate 154. These configurations provide smooth and uniform fluid flow that is easily controlled across the entire surface of the semiconductor substrate because the fluid is not disrupted upon contact with the substrate 150. Essentially, the substrate 150 is integrated into the reaction chamber, such that it acts or becomes a part of the reaction chamber itself.

The reaction chamber 156 may be configured to be a narrow gap, which may be configured to have a height in the range of 2 to 20 times higher than the thickness of the semiconductor substrate 150 itself, and in some embodiments is approximately 10 times the height of the semiconductor substrate 150 being processed. Thus, the space between a bottom wall of the first plate 152 and a top wall of the second plate 154 may be in the range of 1 cm, though in some embodiments it may be in the range between 2.5 cm and 5 cm. Advantageously, by having a low height the reaction chamber 156 provides precise control of the fluid movement across the surface of the semiconductor substrate, caused by the lack of space for convection forces to alter the fluid's motion. However, the present invention contemplates reaction chambers 156 with gap sizes of any desired height by modifying the distance between the first plate 152 and second plate 154. For example, the gap size can be selected at any value desired for the integrated circuit being constructed and the semiconductor substrate being processed. Following, the gap size may be a process variable controllable by an operator.

The linear reactor system may be adjusted to fit any flat substrate, including flexible films or sheets, as well as all wafer sizes. The substate need only lay flat and flush against either plate wall. By doing so, the substrate becomes flush with the internal sides of the plates, which allows fluid to flow over the substrate without disrupting the established fluid motion.

As previously stated, the linear reactor system includes a reactor consists of two flat, square or rectangular parallel plates that serve as the main surfaces of the reactor. The fluid media is introduced into one side of the reactor and exits in a straight path on the opposite side. This configuration ensures a uniform progression of the fluid media, regardless of its temperature, pressure, flow rate, or viscosity, as long as the pressure at the inlet and outlet is even over each width. This makes it ideal for fluid management in nanodevice manufacturing.

Despite the forced convection forces at play, the fluid progression in the reaction chamber remains uniform. The benefits of fluid management are pronounced when the application allows for a thin or small gap between the parallel plates. This restricts the fluid motion in the z-direction, making the forced convection forces uniform along any reactor cross-section, ensuring uniform distribution throughout the reactor channel.

With the substrate fitted into the wall of the reactor, the fluid motion remains undisturbed, continuing down the channel in a self-repeating uniform motion over the reactor area. This applies to gas, plasma, and liquid phase media, allowing manufacturing applications to utilize forced convection without relying on the typically more uniform free convection and long-distance diffusion forces in today's vacuum processes. The thin parallel gap characteristic formed by the linear reactor serves as a main contributor to the desirable fluid dynamics for chemical additive and subtractive manufacturing as it relates to the substrate as a part of the wall of the reactor.

This way, a universal solution of fluid coordination can be realized and applied to a wide range of additive and subtractive manufacturing applications.

The linear reactor system of the present invention is advantageous over reactors found in the prior art. Prior art reactors typically utilize a “shower head” or free convection fluid distribution configuration where process fluid is dispensed into a reaction chamber unevenly relying on free convection and long-distance diffusion forces to even out fluid delivery onto a substrate. In contrast, the linear reactor system of the present invention utilizes an elongated and substantial rectangular reactor that houses a substrate flush with the walls of the reaction chamber to enable uniform forced convection forces for better management of fluid as it flows from one end to another. The linear reactor system of the present invention is advantageous over the prior art reactors in that fluid may be controlled to produce uniform forced convection flow utilizing much wider range of delivery rates for uniform substrate processing and defect management.

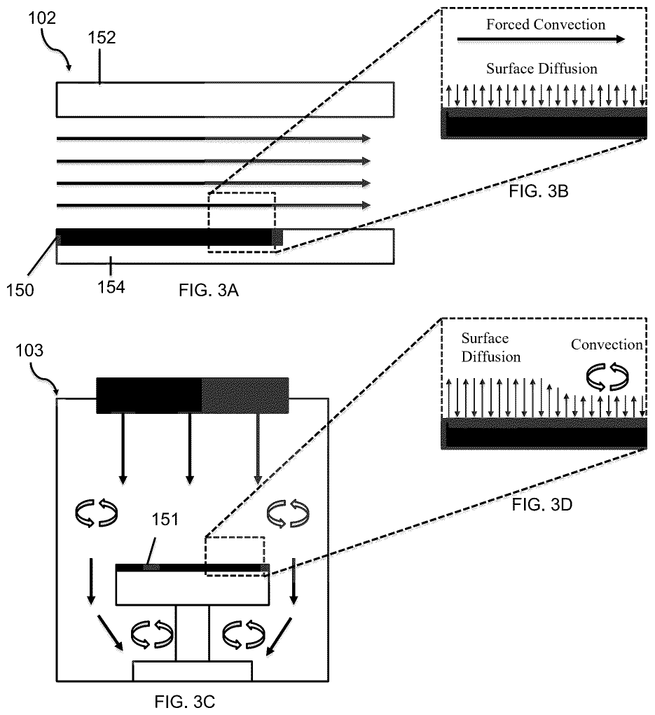

FIGS. 3A-3B illustrates the surface diffusion and forced convection forces at play within the linear reactor 102 of the present invention while FIGS. 3C-3D illustrates the same forces at play within a prior art reactor 103. The prior art reactor 103 includes a spacious reaction chamber with a showerhead-like fluid management system where the fluid is dispersed downward onto the substrate 151 into an exhaust or outlet (as represented by the arrows of FIG. 3C). The substrate 151 is elevated on a platform above a fluid exhaust. Here, the fluid moves downward from a fluid source positioned above the substrate 151, to an exhaust positioned below the substrate 151. Due to the ample space present in the prior art reactor 103, convection forces are likely to disrupt the uniformity of the diffusion occurring at the surface of the substrate 151. This is likely to cause imprecision and imperfect or uneven processing of the substrate 151, in many situations where these forces get too uneven. Particular care and consideration must be taken, such as special showerheads, low flow rates, and exhaust location considerations are required to prevent poor processing. These and other factors limit the effective flow rate and process environment under which a reactor can operate. At the same time, these uniform forced convection forces enable a powerful new tool for defect management as it reduces or eliminates dead zones where defects can hide from chamber purging/self-maintenance.

In contrast to the prior art, the linear reactor 102 of the present invention includes a first plate 152 and a second plate 154 that create a reaction chamber to facilitate fluid movement from one side of the reactor 102 to another (as represented by the arrows of FIG. 3A). Here, the fluid is passed over a top surface of the substrate 150 with little room for the fluid's established motion to be disrupted. Due to the lack of space caused by the narrow gap of the reaction chamber in conjunction with the substrate 150 being positioned in line with or flush with the second plate 154, convection is controlled or forced such that the surface diffusion remains uniform. Regardless of the process conditions, convection forces do not disrupt the uniform flow of fluid. This is unlikely to cause imperfections and causes even and uniform processing of the substrate 150. The uniform forced conversion enables an advantageous tool for defect management as it supports even forces to purge defects from the system unlike any other.

Additionally, FIGS. 3A-3D illustrates the structural difference between the present linear reactor 102 and the prior art reactor 103. The prior art reactor is configured such that fluid is dispensed above and onto the substrate 151. Fluid moves from a top side of the reactor 103, to an exhaust on a bottom side of the reactor 103. Additionally, the substrate 151 is elevated above the exhaust by a pedestal, such that the dispensed fluid makes contact with the substrate 151 and flows downward towards the exhaust. In contrast, the linear reactor 102 of the present invention creates a horizontal linear path for fluid motion. Fluid moves from a fluid source at a first end of the linear reactor 102 to a second end of the linear reactor 102, for example, through an inlet and an outlet. Here, the substrate 150 is flush with or in-plane with the second plate 154, such that it becomes a part of the wall of the reaction chamber. The linear reactor 102 may not include a pedestal to house the substrate 150, rather placing the substrate 150 within the second plate 154, such that it is flush with the walls of the reaction chamber. Advantageously, the linear configuration of the reactor 102 facilitates a uniform fluid profile over a much wider range of flow rates and conditions.

The linear reactor system may further comprise an edge seal to enclose the reaction chamber between the first rigid plate and the second rigid plate. The edge seal may be configured to bind the rigid plates together such that fluid is controlled within the reaction chamber. The edge seal may encompass the reaction chamber and include gaps for the inlet and the outlet. In some embodiments, the edge seal completely encompasses the reaction chamber, such that gaps for the inlet and the outlet may be provided in either of the plates. In some embodiments, the edge seal may be a solid material or a continuation of the first or second plate to establish the gap.

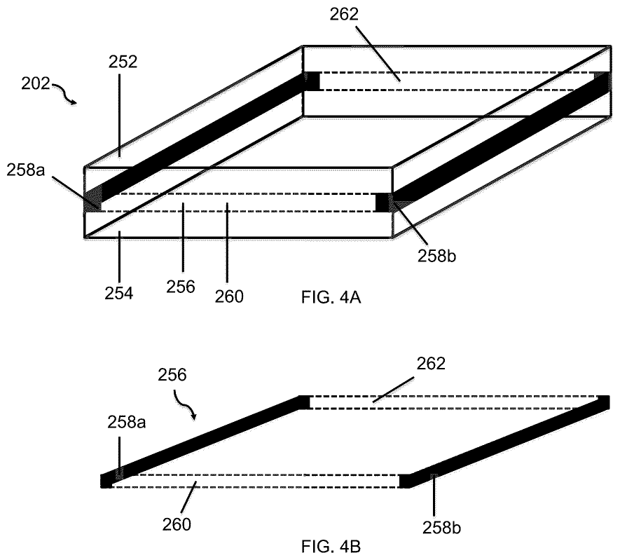

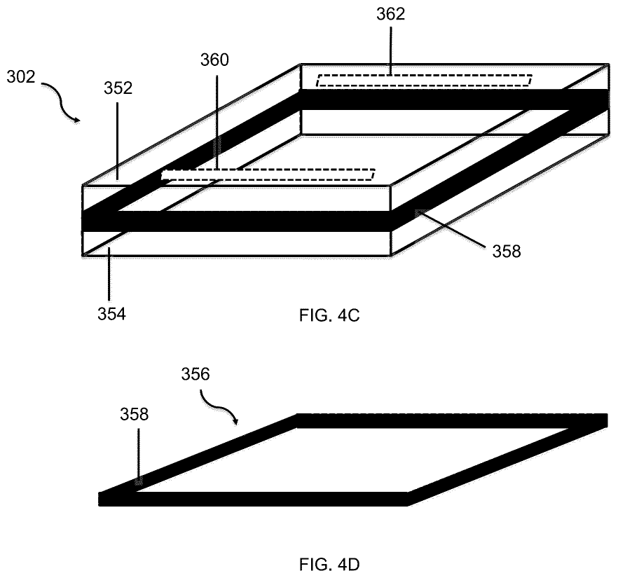

With reference to FIGS. 4A and 4B, an example linear reactor 202 with a sealed reaction chamber 256 is shown. FIG. 4B illustrates the reaction chamber 256 of FIG. 4A. The example linear reactor 202 may be substantially analogous to the example linear reactor 102 and may include: a first plate 252, a second plate 254, and a reaction chamber 256. The example linear reactor 202 may also include an edge seal (258a, 258b), which connects the first plate 252 and the second plate 254 together. The edge seal (258a, 258b) may be configured to connect the plates (252, 254) and create an airtight, watertight, or fluid-tight seal, such that the fluid is contained within the reaction chamber. Additionally, the edge seal (258a, 258b) may not fully encompass the reaction chamber 256, rather leaving a fluid inlet 260 at one end of the reactor 202 for fluid input and a fluid outlet 262 at another end of the reactor 202 for fluid output. FIG. 4B illustrates the linear and rectangular form of the reaction chamber 256. The reaction chamber 256 may be a narrow gap formed between two rigid plates connected by an edge seal so that the fluid may be controlled therein.

With reference to FIGS. 4C and 4D, an example linear reactor 302 with a sealed reaction chamber 356 is shown. FIG. 4D illustrates the reaction chamber 356 of FIG. 4C. The example linear reactor 302 may be substantially analogous to the example linear reactor 202 and may include: a first plate 354 and a second plate 354 connected by an edge seal 358 to form a reaction chamber 356. In some embodiments, as illustrated in FIGS. 4C and 4D, the edge seal 358 fully encompasses the reaction chamber 356. The linear reactor 302 may be constructed with a fluid inlet 360 and a fluid outlet 362 formed in one of the rigid plates (e.g., the first plate 352 as illustrated in FIG. 4C). While not specifically illustrated in FIG. 4C, the reaction chamber 356 may extend up into a fluid management system fluidly connected to the reaction chamber 356 through fluid inlet 360 or fluid outlet 363.

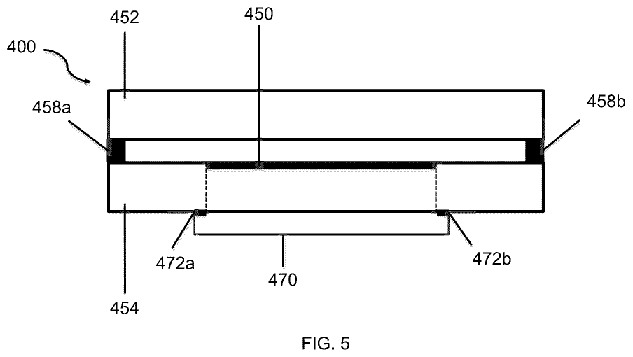

The linear reactor may include several means to housing the substrate for processing and may include additional components to facilitate flush substrate mounting. For example, the linear reactor may include a removable section to load and unload the substrate from one of the plates. The removable section may include a depression to house the substrate. With reference to FIG. 5, an example linear reactor 400 with a removable section 470 for substrate 450 placement is shown. The removable section 470 may be configured to support a substrate 450 and removably attach to the second plate 454. The removable section 470 may include a depression to accommodate the substrate 450. The removable section 470 may be configured such that upon attaching to the second structure 454, the substrate becomes flush with or in plane with the second plate 454. The removable section 470 may comprise a substrate 450, and edge seals 472a, 472b. The seals 472a and 472b may line an exterior surface of the removable section 470, such that upon attachment the reaction chamber is sufficiently sealed to prevent any fluid leakage or pressure change. In other regards the linear reactor 400 of FIG. 5 may be substantially analogous to the example linear reactor 202 and may include: a first plate 452, a second plate 454, and an edge seal 458a, 458b. In some embodiments, the removable section 470 may be supported by a pedestal equipped with rotational means. In these embodiments, the removable section 470 may be operable to rotate the substrate 450 during chemical processing. Advantageously, this provides operators with further modifiable parameters to provide manufacturing solutions.

The present invention contemplates other methods of loading the substrate onto the linear reactor. For example, the first or second plate may be manufactured with a depression on the reaction chamber side of the plate. In this example, the depression is configured to house the substrate, such that it lay flush within the walls of the reaction chamber for processing. In another example, the linear reactor is configured to include plates that are of a size to match that of the substrate. In this example, the substrate covers an entire surface area of the plate, thus becoming flush with the walls of the reaction chamber and not disturbing the established fluid flow. Stated otherwise, by including a substrate into the linear reactor that spans the entire length of the rigid plate, the reaction chamber maintains a smooth and featureless surface so that the substrate may be processed in accordance with the present invention.

### Fluid Management and Fluid Delivery

The linear reactor system may include a fluid management system operable to facilitate a uniform flow of fluid into and out of the reaction chamber. The fluid management system may comprise fluid management devices. The fluid management system may be generally provided at the ends of the linear reactor and in fluid communication with an inlet and outlet of the linear reactor. Generally, the fluid management system may comprise circulating configurations, single-use configurations, or other fluid management configurations known in the art. The fluid management system may establish a flow of fluid into the reaction chamber and establish a fluid motion to be maintained as it flows through the reaction chamber. The fluid management system may induce a constant flow of fluid. The fluid management system may induce a pulsed flow of fluid at predetermine intervals. The fluid management system may further create a pressure differential between two fluid management modules positioned at opposing ends of the linear reactor. The fluid management system may provide an even pressure at the inlet and outlet of the linear reactor.

The linear reactor may be functionally connected to a fluid management system and fluid delivery system operable to cause fluid to pass over the substrate in the reaction chamber from one end of the linear reactor to another. This fluid management system may comprise at least two hydraulic devices fluidly connected to the reaction chamber operable to induce fluid into the reaction chamber and receive or draw fluid from the reaction chamber.

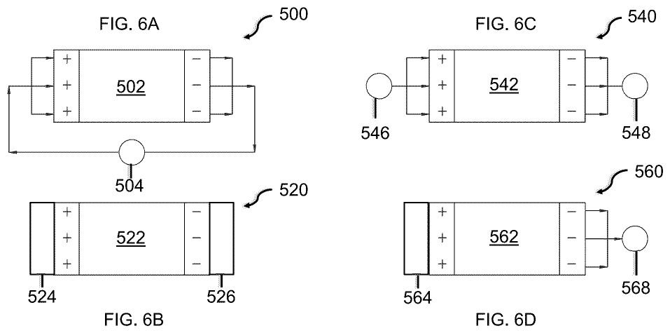

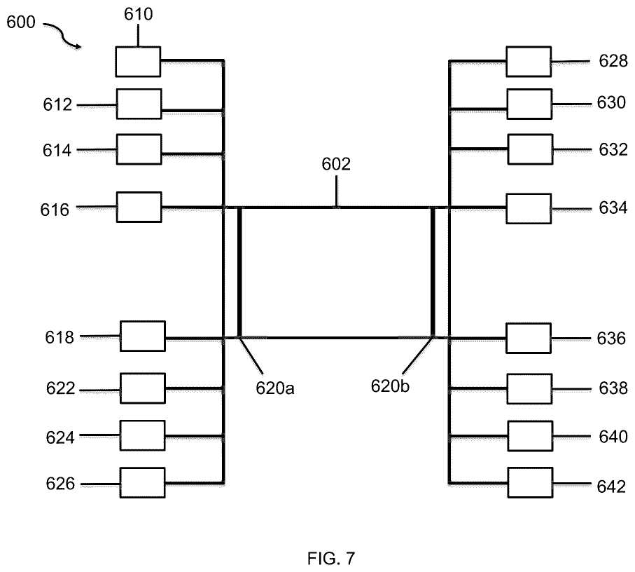

FIGS. 6A-6D illustrate example linear reactor systems (500, 520, 540, 560) with various example fluid management systems. FIGS. 6A and 6B illustrate circulating configurations while FIGS. 6C and 6D illustrates single-use configurations. With reference to FIG. 6A, the example linear reactor system 500 may include a fluid management system comprising a pump 504 fluidly connected to the reaction chamber of the linear reactor 502 operable to induce a flow of fluid through the linear reactor 502, such that the fluid is circulated throughout the linear reactor system 500. In this example, the pump 504 may be fluidly connected to the reaction chamber of the linear reactor 502 through tubing, piping, or other fluid transfer means. With reference to FIG. 6B, the example linear reactor system 520 may include a fluid management system with a direct drive mechanism comprising a fluid inlet module 524 and a fluid outlet module 526 both fluidly connected to the reaction chamber of the linear reactor 522 and operable to induce a flow of fluid through the linear reactor 502, such that the fluid is circulated or oscillated throughout the linear reactor system 520. In this example, the direct drive mechanism may comprise two hydraulic devices with fluid volumes and pistons placed therein to directly drive in the fluid and directly drive out the fluid simultaneously. In this example, the fluid input module 524 is operable to induce the fluid into the reaction chamber while the fluid outlet module 526 is operable to draw the fluid from the reaction chamber. The example linear reactor 520 comprising the direct drive fluid management system may be substantially analogous to the example linear reactor 102 of FIG. 1 that includes fluid management devices comprising a fluid volume, a piston, a fluid manifold, and a gate load lock to effectuate the direct drive mechanism.

With reference to FIG. 6C, the example linear reactor system 540 may include a fluid management system comprising a fluid supply 546 and a fluid waste 548 both fluidly connected to the reaction chamber of the linear reactor 542 operable to induce a flow of fluid through the linear reactor 542. In this example, the fluid is induced into the reaction chamber by the fluid supply 546 and exits the reaction chamber to the fluid waste 548. With reference to FIG. 6D, the example linear reactor system 560 may include a fluid management system comprising a fluid inlet module 564 and a fluid waste 568 both fluidly connected to the reaction chamber of the linear reactor 562 operable to induce a flow of fluid through the linear reactor 562, such that fluid is induced into the linear reactor system 560. In this example, the fluid input module 564 may be substantially analogous to the fluid input device 110 of FIG. 1.

The fluid management system of the linear reactor system may be operable to select a plurality of fluid medias from a fluid library to be introduced into the reaction chamber. These fluid medias may be selectively provided to the reaction chamber such that the operator may facilitate multiple substrate processing steps with a single reactor.

The fluid management system may include a fluid delivery system fluidly connected to several different fluid modules (collectively referred to as a fluid library) and operable to induce several different fluid media into the reaction chamber of the linear reactor. With reference to FIG. 7, a schematic diagram of an example fluid delivery system 600 of an example linear reactor 602 is shown. Often, substrates require passage of multiple different fluids in order to perform a required additive or subtractive process to fabricate electrical circuits thereon. The fluid delivery system 600 provides the means to accomplish such fabrication by selectively passing fluid through the reaction chamber of the linear reactor 602.

The example fluid delivery system 600 may include a linear reactor 602, gate load locks (620a, 620b), and be fluidly connected to several different fluid medias (610, 612, 614, 616, 618, 622, 624, 626, 628, 630, 632, 634, 636, 638, 640, 642) (collectively referred to as a “fluid library”). The fluid delivery system 600 may further include means to select which fluid media to induce into the linear reactor 602, such that an operator may facilitate multi-step processes with a single reactor. As an example, the fluid library may comprise an inert gas, a precursor, deionized water, and/or other chemical or fluid desirable for reaction. Additionally, the linear reactor system may be fluidly connected to other modules operable to affect an environment of the reaction chamber. For example, the other modules may comprise a vacuum, a gas exhaust, a waste, and/or a drain. Furthermore, the example fluid delivery system 600 may be functionally connected to any fluid management system described herein or known in the art operable to induce and/or draw out said fluid medias. The gate load locks (620a, 620b) may be configured to isolate the reaction chamber of the linear reactor 602 from the fluid media or allow passage of the fluid media. In order to process a substrate placed within the linear reactor 602, the fluid delivery system 600 selects a specific fluid media to be induced within the reaction chamber depending on the needs. Selection may be accomplished by inclusion of a fluid manifold.

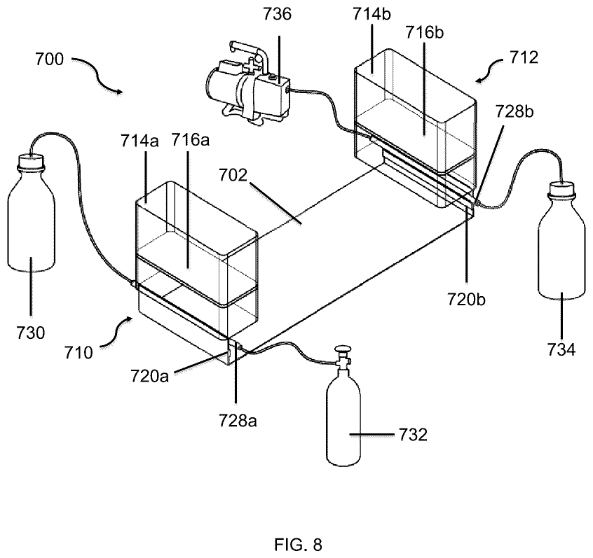

With reference to FIG. 8, an isometric view of an example fluid delivery system 700 shown. The fluid delivery system 700 may be fluidly connected to several fluid medias (e.g., 730, 732, and 734) and fluidly connected to at least one environment altering module (e.g., vacuum 736). The fluid medias (730, 732, and 734) and environment altering module 736 may be induced into the reaction chamber of the linear reactor 702 by a fluid management system, such as a manifold. The fluid delivery system 700 may enable an operator to select which fluid, or environment module, to provide to the substrate. For example, initially the reactor 702 may be purged with a high velocity inert gas from fluid media 732 to clear any particle defects, then a vacuum may be provided within the reaction chamber by module 736, followed by introduction of fluid from fluid media 730, and finally introduction of fluid from fluid media 734. As another example, fluid from fluid medias 730, 732, 734 may each be induced into the linear reactor 702 one after another, or according to process need, with a vacuum provided in between steps to clear the reaction chamber of any remaining fluid, ensuring clean processing of the substrate.

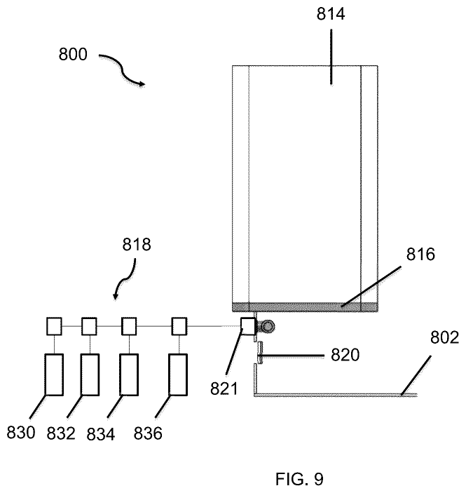

FIG. 8 illustrates the modularity of the linear reactor system and how inclusion of a fluid delivery system enables an operator to effectuate a desired fabrication process through a plurality of steps comprising introduction of fluids into the reaction chamber. The fluid delivery system 700 of FIG. 8 may be included in the example linear reactor system of FIG. 1 and consequently include fluid management devices comprising: a fluid input module 710 and fluid output module 712 each including a fluid volume (714a, 714b), a piston (716a, 716b), a fluid manifold (728a, 728b), and a gate load lock (720a, 720b). Furthermore, the fluids, vacuums, exhaust, and waste drains may be connected to a manifold to effectuate selective introduction into the reactor 702, such as the fluid manifold 818 of FIG. 9.

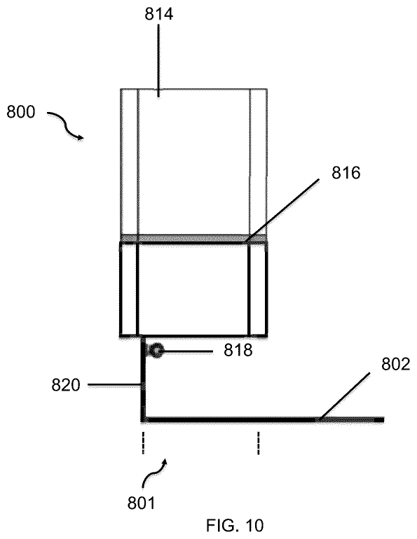

FIGS. 9 and 10 illustrate an example direct drive fluid input module 800 or “fluid management device” operable to selectively draw in a fluid from a fluid module (830, 832, 834, 836) or “fluid library” to a fluid volume (814) for introduction into the linear reactor 802. The fluid modules of FIGS. 9 and 10 may be hydraulic devices and substantially analogous to those modules described with reference to FIG. 1. FIG. 9 illustrates the fluid input module 800 prior to fluid introduction. The fluid input module may be configured to drawn in a selected fluid (e.g., 830, 832, 834, or 836) to the fluid volume 814 by the piston 816. During this process, the fluid manifold 818 may be operable to select which fluid to be drawn while the gate load lock 820 isolates the linear reactor 802 from the fluid volume 814. Additionally, the fluid manifold 818 may include an isolation valve 821 to isolate the fluid volume 814 from the fluid media following drawing of the fluid into the fluid volume 814. The fluid manifold 818 may be configured to selectively control the fluid coupling of each fluid of a plurality of fluids from a fluid library, such as that illustrated in FIG. 7. This system enables an operator to select a fluid and provides the means to induce said fluid into the reaction chamber for chamber preparation, chemical processing, or substrate processing.

For clarity, the fluid management devices of the present invention may include an isolation valve 821 to isolate a fluid volume from a fluid library, such as that illustrated in FIG. 7. This enables selection of a specific fluid to draw into the fluid volume 814 and upon the desired amount of fluid being drawn in, isolate the fluid volume from the fluid library to avoid back flow or contamination. Additionally, the fluid management devices of the present invention may include a gate load lock 820 to isolate the fluid volume 814 from the interior volume of the linear reactor 802 (i.e., reaction chamber), such that no fluid enters the reaction chamber as fluid is being drawn into the fluid volume 814. By including fluid management devices with an isolation valve 821 and gate load lock 820, the present invention enables precise control of fluid that enters and exits the reaction chamber.

FIG. 10 illustrates the fluid input module 800 during fluid introduction and highlights the entrance region 801. Following drawing in a fluid to the fluid volume 814 and opening of the gate load lock 820, the fluid may be introduced into the reaction chamber of the linear reactor 802 by a piston 816. The linear reactor 802 may include an entrance region 801 positioned substantially at an end of the linear reactor 802 where a fluid motion is established. The entrance region 801 may be an area in the reaction chamber where fluid enters prior to making contact with a substrate. The entrance region 801 may establish the fluid flow for the remainder of the reaction chamber. The entrance region 801 may be adjusted with setup variable. For example, the entrance region 801 may be adjusted by the gap distance of the reactor 802, the flow rate, or by mesh or matrix materials in line with the reaction chamber to minimize the length of the entrance region 801 so that a constant convection profile is consistent over the substrate or reaction area of the reaction chamber.

The fluid may have an initial velocity that equals the velocity of the piston 816 as it exerts force onto the fluid contained within the fluid volume 814. Once the fluid enters the entrance region 801, the fluid exhibits an amplified velocity while the mass flow rate remains constant. This may be due to the size or volume configurations of the fluid volume 814 and reaction chamber. The cross-sectional area of the fluid volume 814 may be at least forty times that of the cross-sectional area of the reaction chamber. However, the fluid management system may be constructed with a cross-sectional area of fluid volume less or greater than forty times that of the cross-sectional area of the reaction chamber. For example, the cross-sectional area of the fluid volume 814 may be on hundred times that of the cross-sectional area of the reaction chamber. As the fluid exits the larger area of the fluid volume 814 into the smaller area of the reaction chamber, the velocity may increase.

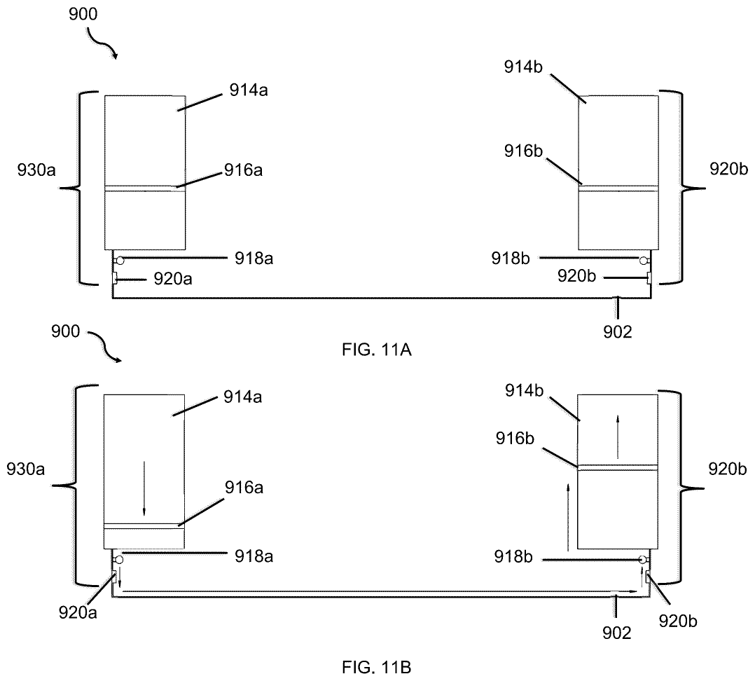

Referring to FIGS. 11A and 11B, an example linear reactor system 900 is shown. Particularly, FIGS. 11A and 11B illustrate a direct drive fluid management system comprising hydraulic devices (930a, 930b) for inducing a fluid into the example linear reactor system 902. The linear reactor system 900 may include a first hydraulic device for fluid input 930a and a second hydraulic device for fluid output 930b. Each hydraulic device (930a, 930b) may include a fluid volume (914a, 914b), a piston (916a, 916b), a fluid manifold (918a, 918b), and a gate load lock (920a, 920b). The hydraulic devices (930a, 930b) may be in fluid communication with a linear reactor 902. The pistons (916a, 916b) may be configured to work in tandem to induce a uniform flow of fluid. For example, as piston 916a exerts a force onto the fluid contained within the fluid volume 914a, piston 916b exerts an equal or substantially equal force in the opposite direction drawing fluid from the linear reactor 902. The pistons (916a and 916b) may be configured for independent or asynchronous flow to adjust pressure or to assist in high-frequency pulse processing. Advantageously, this configuration causes a pressure differential to support the uniform fluid motion with the reaction chamber.

Piston motion may be used for pushes, pulls, and other fluid control mechanisms. The fluid to be input can be provided via various tubing on the input side or can be placed in the fluid volume 914a with the piston 916a operable to press down with force in order to inject the fluid into the reaction chamber. The fluid volumes (914a, 914b) may have a volume including a cross-sectional area that is in the range of 1 to 100 times larger than the cross-sectional area of the reaction chamber. The fluid volumes (914a, 914b) may have a width equivalent to or substantially equivalent to a width of the internal volume of the reaction chamber. Accordingly, the piston 916a can move very slowly to force the fluid out of the fluid volume 914a and into the reaction chamber as shown by the various arrows going down slowly and then, once entering the reaction chamber of the linear reactor 902, moving with increased velocity in the narrow channel from the inlet to the outlet. Once the fluid reaches the outlet, it can be taken up by the fluid volume 914b that withdraws the fluid from the reaction chamber of the linear reactor 902. The fluid may also be directed out of the reaction chamber to a waste or vacuum exhaust through selection by a manifold.

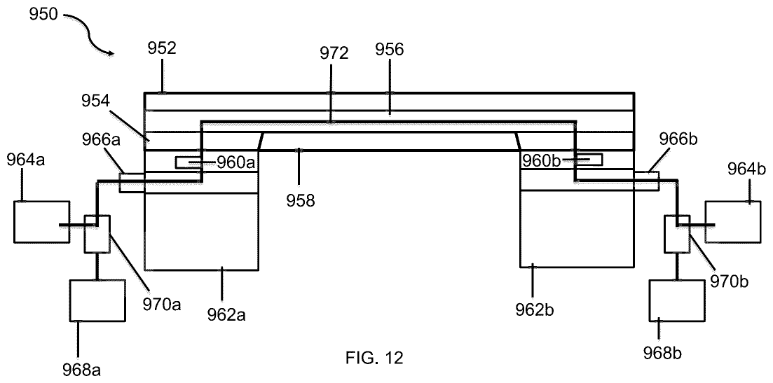

Referencing FIG. 12, an example linear reactor system 950 is shown. FIG. 12 illustrates an example linear reactor system 950 configured for chemical processing and highlights the moving parts operable to facilitate said processing. Furthermore, FIG. 12 highlights the fluid flow path 972 for fluid used to process a substrate placed therein (not displayed for illustrative purposes). The example linear reactor system 950 may include a first plate 952 and a second plate 954 with a reaction chamber 956 formed there between. The second plate 954 may include a removable section 958 in order to accommodate a substrate for placement within the reaction chamber 956. The removable section 956 may include the components of the removable section 470 illustrated in FIG. 5 and function in a substantially similar way. The linear reactor system 950 may include gate load locks (960a, 960b) positioned at inlets and outlets to the reaction chamber 956 operable to isolated said reaction chamber from fluid modules (962a, 962b). The linear reactor system 950 may be fluidly connected to vacuum modules (964a, 964b) and fluid sources (968a, 968b) through isolation valves (966a, 966b) and fluid manifolds (970a, 970b). The pressure differential may be generated by input from a bottle, pump, vacuum, or direct drive of a push cylinder module (e.g., FIGS. 11A and 11B).

In order to effectuate chemical processing, initially, the reaction chamber 956 and fluid flow path 972 may be evacuated by the vacuum modules (964a, 964b). The vacuum models may be selected by the fluid manifolds (970a, 970b). Next, the gate load locks (960a, 960b) may be closed and the isolation valves (966a, 966b) may be opened. Then, a fluid from fluid source 968a may be drawn into the fluid module 962a upon selection by the fluid manifold 970a, followed by closing of the gate load lock 960a and opening of the isolation valve 966a. Following this, the fluid may be dispensed into the reaction chamber 956 through the fluid flow path 972 by the fluid module 962a upon closing the isolation valve 966a and opening the gate load lock 960a. Simultaneously, the fluid may be drawn out of the reaction chamber 956 through the fluid flow path 972 by the fluid module 962b upon opening the gate load lock 960b and closing the isolation valve 966b. In this way, a uniform fluid flow may be induced into the reaction chamber over a substrate in order to process the substrate. As will be discussed in more detail later, as fluid is being passed over a surface of the substrate, a linear reactor framework may be operable to control a variety of parameters, for example temperature or pressure of the reaction chamber 956 or flow rate, ionization, or activation energy of the fluid.

Following the above-described process, the reaction chamber 956 may be purged to be prepared for subsequent manufacturing steps. For example, a different fluid may be selected by the fluid manifold 970a and induced into the reaction chamber 956 and drawn into a waste utilizing the gate load locks (960a, 960b), isolation valves (966a, 966b), and fluid manifold 970b.

### Framework

The linear reactor system may be supported by a linear reactor framework operable to provide a wide variety of supporting modules to affect the environment of the reaction chamber or affect the properties of the fluid prior to or during substrate fabrication. The linear reactor framework is a framework for facilitating removable attachment of various support modules in order to modify the linear reactor to meet the specific manufacturing needs of the operator. The various supporting modules may be placed at various locations relative to the linear reactor. For example, the supporting modules may be placed on the sides, above, below, within, and/or at an angle to the linear reactor. The linear reactor framework provides operators with the means to effectuate various manufacturing steps for substrate processing, nanodevice manufacture, and lends itself to the adaptability of the present invention.

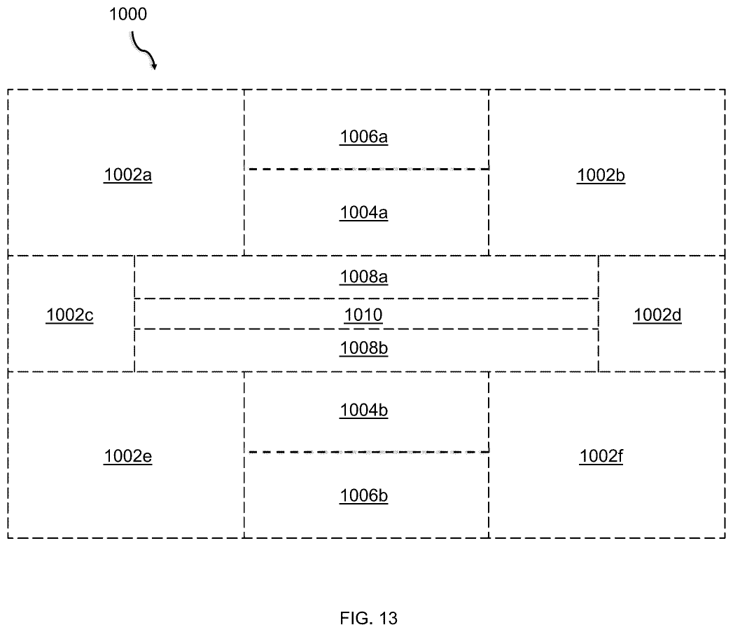

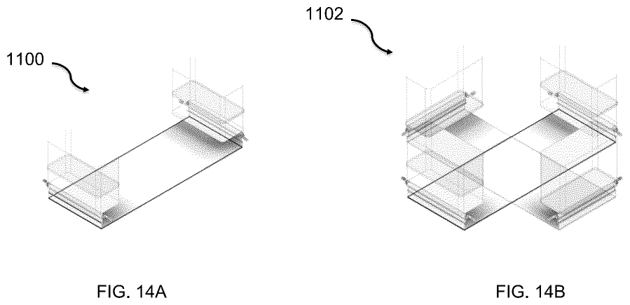

Referencing FIG. 13, a block diagram schematic of an example linear reactor framework 1000 is shown. The linear reactor framework 1000 may comprise support modules (1002a, 1002b, 1002c, 1002d, 1002e, 1002f), substrate handling modules (1004a, 1004b), alteration modules (1006a, 1006b), plate modules (1008a, 1008b), and at least one side module 1010. The various linear reaction framework modules may be operable to support a wide variety of linear reactor configuration. For example, the modules may be configured to support chemical compatibility, process temperature, process pressure, process flow rate, process uniformity or selectivity, ionization and activation energies, substrate handling, safety interlocks, system controls, fluid dead leg reduction, and other configuration for supporting substrate processing known in the art. For clarity, the modules described with reference to FIG. 13 may include the fluid management systems, fluid management devices, fluid delivery systems, and example linear reactor systems previously discussed.

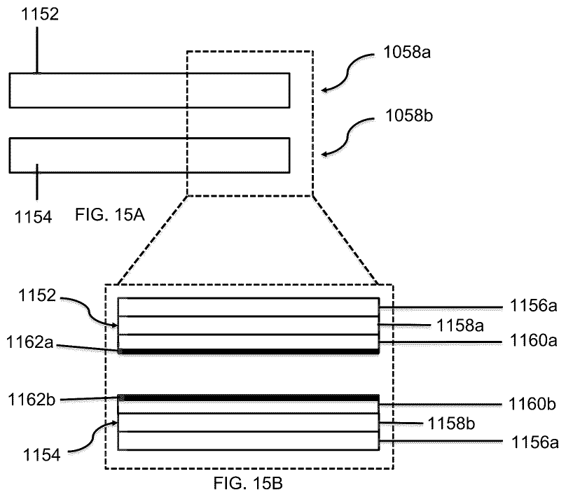

The plate modules (1008a, 1008b) may include the plates of the linear reactor system that form the walls to the reaction chamber. The plate modules (1008a, 1008b) may be positioned in substantially the center of the linear reactor framework 1000. The plate modules (1008a, 1008b) may comprise two rigid plates positioned off-set and parallel to one another in a substantially rectangular configuration. The plate modules (1008a, 1008b) may form the reaction chamber through a gap created there between. The plate modules (1008a, 1008b) may be configured to provide certain properties or integrate certain components. For example, the plate modules (1008a, 1008b) may provide, pressure containment, sensor integration, ionizing and activation energy inputs, substrate handling, and temperature control. The plate modules (1008a, 1008b) may include the plurality of layers and liners described in reference to FIGS. 15A and 15B. The plate modules (1008a, 1008b) may include means to affect electric properties of the fluid prior to or during introduction into the reaction chamber, for example by inclusion of at least one electrode.

The support modules (1002a, 1002b, 1002c, 1002d, 1002e, 1002f) may include the fluid management systems, devices, and fluid delivery systems previously discussed and are positioned substantially near the ends of the linear reactor framework 1000. The support modules (1002a, 1002b, 1002c, 1002d, 1002e, 1002f) may provide control measures for introduction of fluid to the reaction chamber. For example, the support modules (1002a, 1002b, 1002c, 1002d, 1002e, 1002f) may provide, fluid uniformity control, flow rate control, temperature control, pressure control, ionizing and activation energy inputs, media filters, gate control, and a variety of sensor integration. Additionally, the support modules (1002a, 1002b, 1002c, 1002d, 1002e, 1002f) may provide support for physical configurations, such as support for stacking multiple linear reactor frameworks together or mounting linear reactor frameworks to specific surfaces. Additionally, the support modules (1002a, 1002b, 1002c, 1002d, 1002e, 1002f) may be functionally attached to the linear reactor in a variety of positions. For example, the support modules (1002a, 1002b, 1002c, 1002d, 1002e, 1002f) may be positioned parallel to, in plane with, above, or below the linear reactor (comprising the plate modules 1008a and 1008b).

The side module 1010 may include the edge seal previously discussed and is positioned substantially in the center or on the side of the linear reactor framework 1000. The side module 1010 may provide means for measuring characteristics of the reaction chamber. For example, the side module 1010 may support gap size control, sensor integration, ionizing and activation energy input integration, and pressure control.

The substrate handling modules (1004a, 1004b) may provide support for including the substrate into the reaction chamber. The substrate handling modules (1004a, 1004b) may include the removable section previously described or the depression in the rigid plate previously described. The substrate handling modules (1004a, 1004b) may be positioned adjacent to the plate modules (1008a, 1008b).

The alteration modules (1006a, 1006b) may provide support for altering properties of the plate modules (1008a, 1008b) or affecting an environment of the reaction chamber. For example, the alteration modules (1006a, 1006b) may support ionizing and selective energy inputs, metrology instruments, or other sensor support. The alteration modules (1006a, 1006b) may be positioned adjacent to the substrate handling modules (1004a, 1004b).

The linear reactor framework may be constructed to support various configurations. For example, a side module can be located at the left and right hand sides of the linear reactor, and modules on the sides may be present on either end of the linear reactor. On top of the reaction chamber may be a plate module acting as the top wall and underneath the chamber is another plate module, acting as the bottom support wall. Various modules can be on the left and right sides of the reaction chamber to provide different functions, such as providing an electrical current, providing an electric field, providing inflow of different materials whether dopants, materials to be deposited, metals for deposition, or other materials used in the manufacture of integrated circuits in semiconductor processing.

Various substrate handling modules may be provided at the top and bottom of the linear reactor and support modules can be provided along the edges as well. Among the modules that may be provided are those to control the process temperature, the process pressure, the flow rate ionization and activation energies, substrate handling safety, system controls, and fluid reaction.

The linear reactor centered within the framework is designed to be flat and allows for fluid management from side-to-side. This design provides ample space for the activation or ionization of energy inputs closest to the substrate. This feature allows for great flexibility in adapting solutions for selective or uniform activation reactions. The energy inputs facilitate a chemical reaction by providing the required energy to make the reaction favorable. These energy inputs can be in the form of IR heating or cooling, UV, visible, Microwave, RF, Sonic, nuclear, or any other form of energy that can facilitate a chemical reaction, including creating a plasma. These energy modules can be adapted to various locations above, below, or any side of the linear reactor.

The framework's support modules may be designed to manage the flow of fluid in and out of the linear reactor. They enable you to control the temperature, pressure, flow rate, and activation of the incoming or outgoing fluid. Each module may be tailored to the width of the reactor, and adding more modules may increase the overall length of the continuous fluid path.

The potentially useful modules include Passive Fluid Distribution, Gate Valve control, Primary Pressure Regulation, Secondary Pressure Regulation, Direct Drive Pressure Regulation, Filter, Heater, Cooling, Ionization Energies, Electrodes, Sensors, Sonic Energy, Vapor Generator, and others.

The linear reactor framework is designed to combine the needs of chemical additive and subtractive manufacturing of nanodevices using flexible solutions that can be adapted to specific application requirements. This approach can lead to significant efficiency gains, making the complex process of manufacturing nanodevices more efficient and manageable.

The linear reactor framework is not limited to a single framework. The linear reactor framework may include means to support additional frameworks in order to support the desired need. For example, the support modules 1002a, 1002b, 1002c, 1002d, 1002e, or 1002f may include a bracket or scaffolding to mount another linear reactor framework.

Referencing FIGS. 14A and 14B, a single linear reactor framework 1100 and multi-linear reactor framework 1102 are shown. Advantageously, the linear reactor framework of the present invention is of a symmetrical configuration that enables support of additional frameworks. For example, while the linear reactor framework 1100 of FIG. 14A may include a single linear reactor and two fluid management modules, the linear reactor framework 1102 of FIG. 14B may include two linear reactors and four fluid management modules.

The plate modules 1008a, 1008b of FIG. 13 may include a plurality of internal layers and liners placed therein operable to affect an environment of the reaction chamber or chemical properties of the process fluid. Referring to FIGS. 15A and 15B, example plate modules 1058a, 1058b with integrated layers are shown. FIG. 15A illustrates example plate modules 1058a, 1058b each including a plate 1152, 1154, and FIG. 15B provides a magnified view of the plate modules 1058a, 1058b, such that a plurality of internal layers and liners are visible. For ease of illustration the substrate is not included. Each plate (1152 1154) of the plate modules 1058a, 1058b may include a rigid support structure (1156a, 1156b), a thermal isolation layer (1158a, 1158b), an integrated layer (1160a, 1160b), and an integrated liner (1162a, 1162b). The rigid support structure (1156a, 1156b) may serve to support mounting of the various internal layers and liners, such as those not explicitly illustrated herein. The rigid support structure (1156a, 1156b) may not necessarily be positioned on the outer most side of the plate module 1058, rather it may encompass or surround the internal layers and liners.

The thermal isolation layers (1158a, 1158b) may be operable to provide thermal insulation to the reaction chamber. The integrated layers (1160a, 1160b) may include means for heating or cooling the reaction chamber, as well as means for supporting ionization hardware, electrodes, and sensors. Similarly, the integrated liners (1162a, 1162b) may also support means for heating hardware, cooling hardware, ionization hardware, electrodes, and sensors. The integrated layers (1160a, 1160b) may be generally configured within the plate modules 1058a, 1058b while the integrated liners (1162a, 1162b) may be generally configured on an exterior surface facing the reaction chamber of the plate modules 1058a, 1058b.

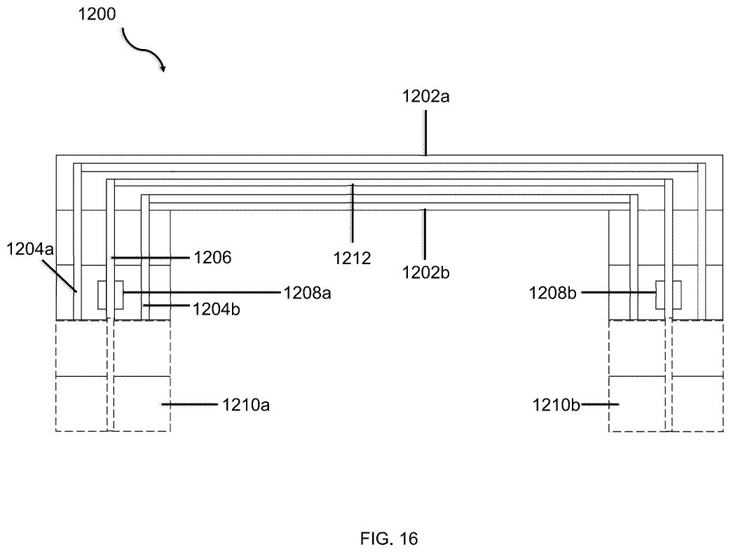

The linear reactor framework may be specifically configured for a number of manufacturing steps. FIGS. 16-24 illustrates example framework configurations to exemplify the adaptability of the linear reactor framework to fit the needs of each manufacturing step necessary for substrate fabrication. For example, the linear reactor framework may provide a module that can be mounted above the top wall of the reactor chamber and provide any desired combination of configurations for applying heat, voltages, drive currents, the introduction of various gases, dopants, and other materials needed for semiconductor processing to manufacture the integrated circuit. Additionally, the linear reactor framework may be configured to provide support for various manufacturing steps and intermediate steps. For example, the linear reactor framework may be configured to provide thermal isolation, heating and cooling capabilities, pressure control, chemical free processing, ALD processing, ionization control and processing, ion etching, electroplating, patterning, and other functions known in the art.

FIG. 16 illustrates a cross-sectional view of an example configuration of the linear reactor framework 1200 with heating and cooling capabilities. A fluid channel 1206 may be provided to fluidly connect support modules (1210a, 1210b) to the reaction chamber 1212. The fluid channel 1206 may extend from the inlet to the outlet of the linear reactor framework 1200. The linear reactor framework 1200 may provide heating and cooling capabilities by including a thermal module (1208a, 1208b) surrounding the fluid channel 1206 positioned near the inlet and outlet of the linear reactor framework 1200 and thermal insulation layers (1204a, 1204b) included in the plate modules (1202a, 1202b). Additionally, a side module may be included, surrounding the reaction chamber 1212 that provides integrated resistive or inductive heating along the fluid channel 1206.

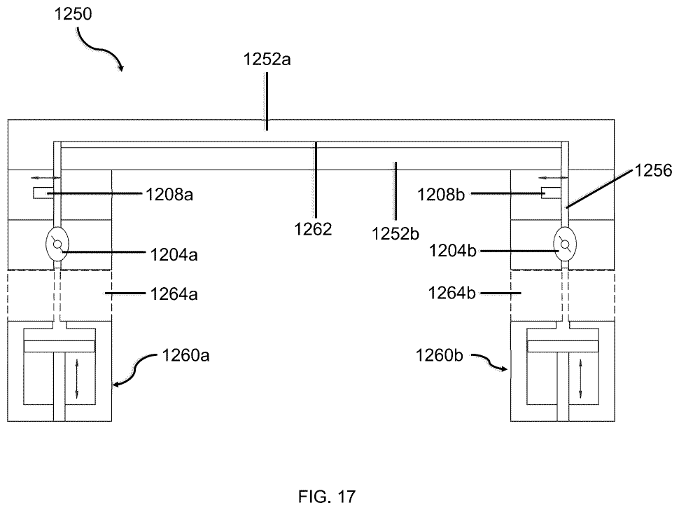

FIG. 17 illustrates a cross-sectional view of an example configuration of the linear reactor framework 1250 with pressure control capabilities. FIG. 17 highlights the different valve arrangements that can be provided along with fluid volumes and drive pistons to provide fluid to the reaction chamber. These can be positioned in a housing that is adjacent to the reaction chamber, for example, above or to the side, as shown in other figures. It can be included in the structure of FIG. 1. A fluid channel 1256 may be provided between two plate modules (1252a, 1252b) to fluidly connect modules of a fluid management system (1260a, 1260b) and support modules (1264a, 1264b) to the reaction chamber 1262. The linear reactor framework 1250 may provide pressure control capabilities by include throttle valves (1204a, 1204b) and gate load locks (1208a, 1208b) positioned near the inlet and outlet of the linear reactor framework 1200.

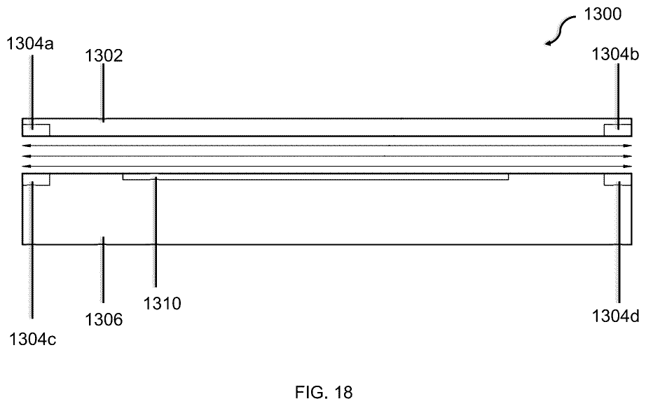

FIG. 18 illustrates a cross-sectional side view of an example linear reactor framework 1300 configured for chemical free processing. The example linear reactor 1300 may include a top plate module 1302, a bottom plate module 1306, and a substrate 1310 placed therein. The example linear reactor 1300 may further include a plurality of electrodes (1304a, 1304b, 1304c, 1304d). The arrows of FIG. 18 illustrate fluid flow through the reaction chamber across an exposed surface of the substrate 1310. The electrodes (1304a, 1304b, 1304c, 1304d) may be positioned within or on the surface of the plate modules (1302, 1306). An aqueous solution may be induced into the reaction chamber and passed over the surface of the substrate 1310 while the electrodes (1304a, 1304b, 1304c, 1304d) may be operable to activate the hydroxide radical of the aqueous solution for non-chemical processing purposes. For example, this configuration may be used for surface treatment and photoresist removal.

Fluid induced into the reaction chamber may be activated by electrodes (1304a, 1304b, 1304c, 1304d) that create ions and free radicals. The electrodes (1304a, 1304b, 1304c, 1304d) may be fitted into the plate modules (1302, 1306) or any support modules downstream or upstream of the substrate 1310 itself in order to activate the fluid. In some embodiments, the electrodes (1304a, 1304b, 1304c, 1304d) have a field applied and current passing through in order to create a plasma so that the entire surface of the substrate 1310 may be covered in a uniform plasma. This can provide process treatment for the entire surface including such steps as photoresist removal, dry etching, wet etching, and the formation of various insulating layers, as well as other process steps in the formation of integrated circuits.

As can be seen in FIG. 18, a small recess is in the plate module 1306, preferably having a depth exactly equal to the thickness of the substrate 1310 to be placed therein. Accordingly, the top surface of the substrate 1310 is flush with the top surface of the plate module 1306.

As previously noted, and as illustrated in FIG. 18, the linear reactor may have a low-profile reactor chamber having a height or gap formed by the space between the plate modules. The reaction chamber has a height equal to the gap between the top and bottom walls and extends longitudinally from a first end to a second end. The height of the reaction chamber, namely the gap, may be in the range of ten times to twenty times greater than the thickness of the substrate 1310 (e.g., semiconductor wafer) being processed. Accordingly, the distance between the top plate module 1302a and the bottom plate module 1302b is low. In some embodiments, the height of the reaction chamber may be less than half a millimeter, while in other embodiments, the height of the reactor chamber may be in the range of 2 to 3 cm, and in other embodiments, the height may be in the range of 5 to 10 cm. However, one of ordinary skill in the art will appreciate that the height of the reaction chamber and the size of the gap may be greater or smaller than specified herein.

The linear reactor framework may be configured to facilitate ALD by inducing a fluid, or multiple fluids, into the reaction chamber such that they pass over the substrate placed therein. The linear reactor framework may include a fluid management system and fluid delivery system operable to induce a constant flow of fluid or a pulsed flow of fluid. Furthermore, the fluid management system may be operable to select fluids for delivery from a library of fluids, such as illustrated in FIGS. 7 and 9. Additionally, the linear reactor framework may include modules to encourage specific reactions to occur on the surface of the substrate, thus effectuating ALD.

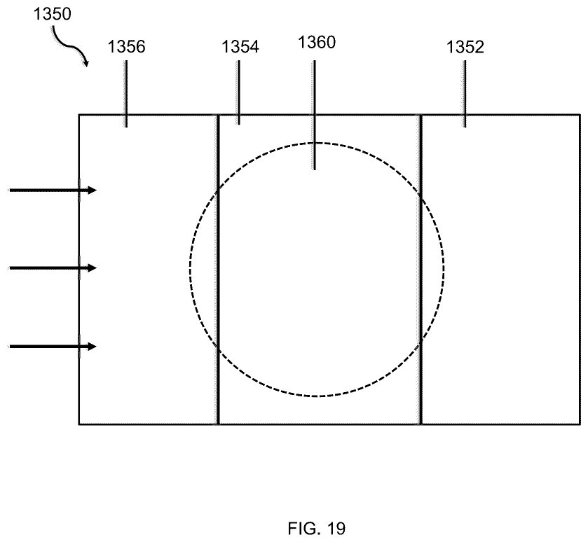

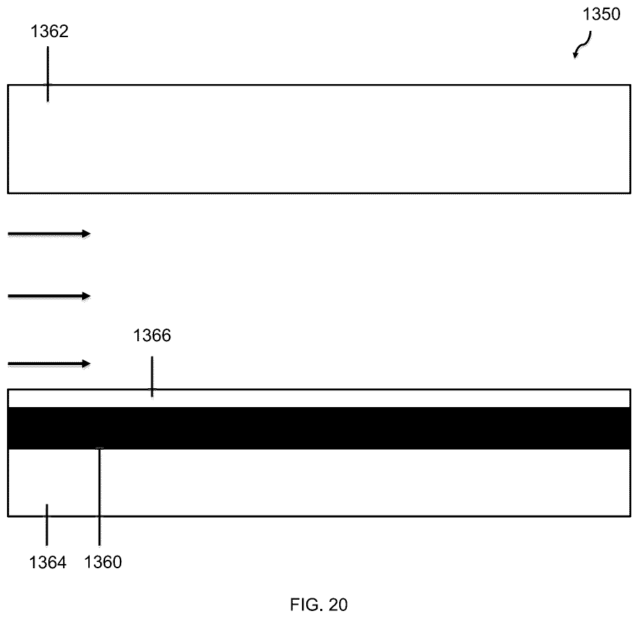

FIGS. 19 and 20 illustrate an example configuration for facilitating ALD onto a substrate. FIG. 19 illustrates a top-down view of an example linear reactor 1350. For ease of illustration, only a bottom plate module is shown, such that the substrate 1360 is shown. As illustrated by the arrows in FIG. 19, fluid may be delivered into the reaction chamber of the linear reactor 1350 and passed over the substrate 1360 from one end of the reaction chamber to another. For example, initially a first precursor fluid 1352 may be introduced into the reaction chamber 1350, followed by an inert gas 1354 to purge the chamber of the first precursor 1352, and lastly a second precursor fluid 1356 is introduced. The precursor fluids (1352, 1356) may react with the surface of the substrate 1360 and form a layer therein.

FIG. 20 illustrates a cross-sectional side-view of the example linear reactor 1350 of FIG. 19 such that the ALD film 1366 is visible. The example linear reactor 1350 may be substantially analogous to the example linear reactor 1300 in that it includes a top plate module 1362, a bottom plate module 1364, and a substrate 1366 placed therein. Furthermore, FIG. 20 illustrates a flow of fluid through the reaction chamber across an exposed surface of the substrate 1360. FIG. 20 illustrates how the fluid may react with the surface of the substrate 1360 and create an ALD film 1366. These plate modules may be equipped with heating capabilities, such that they create a heated wall to aid in the development of the ALD film 1366.

The linear reactor may be configured for chemical mechanical polishing (CMP). This configuration may be substantially similar to that of FIG. 20. In some embodiments, the fluid entering the reaction chamber may include abrasive aggregates. The fluid dynamics between two parallel surfaces allow precision control over all process variables for abrasion of suspended aggregates against the wall surfaces. This method can be used in chemical mechanical processes such as CMP. Variables include fluid viscosity, aggregate size, shape, flow rate, temperature, chemistry, and pressure. When these variables are considered, the linear reactor may employ a process that selectively removes one material while inert to another uniformly over a large surface area. The size and shape of the aggregate can be adjusted to minimize overprocessing and dishing of selected materials upon endpoint.

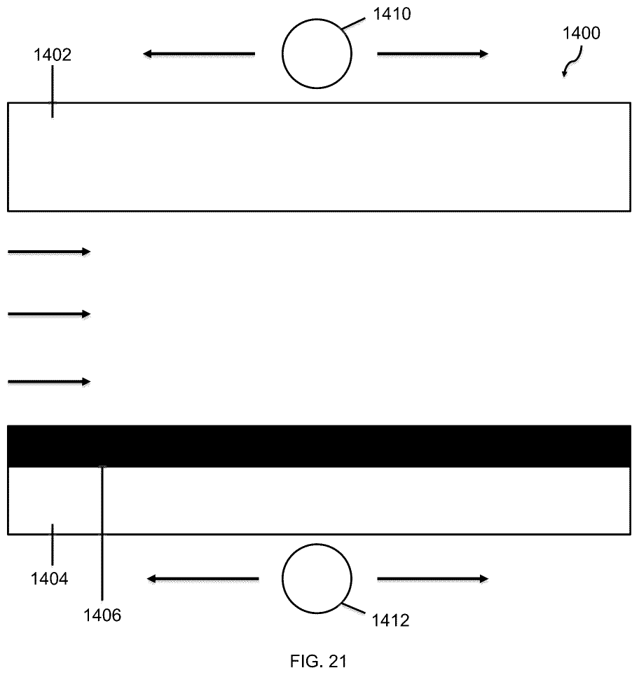

FIG. 21 illustrates a side-view of an example linear reactor 1400 configured for ion implantation. The example linear reactor 1400 may be substantially analogous to the example linear reactor 1300 in that it includes a top plate module 1402, a bottom plate module 1404, and a substrate 1406 placed therein. Furthermore, FIG. 18 illustrates a fluid flow through the reaction chamber across an exposed surface of the substrate 1460. The example linear reactor 1400 may further include a positive electrode 1410 and a negative electrode 1412. The example linear reactor 1400 may be included in a linear reactor framework equipped with supporting modules operable to sweep or move the electrodes (1410, 1412) across the length of the linear reactor 1400, as indicated by the arrows of FIG. 21 in order to affect properties of the fluid. Furthermore, the top plate module 1402 and the bottom plate module 1404 may be equipped with internal thermal layers or liners, such that the plate modules 1402, 1404 are heated or cooled as desired for the specific chemical reaction. Advantageously, upon fluid delivery, this configuration may facilitate ion formation within the reaction chamber applicable for a wide variety of applications (e.g., ion etching, PVD, Plasma-Enhanced Chemical Vapor Deposition (PECVD), etc.).

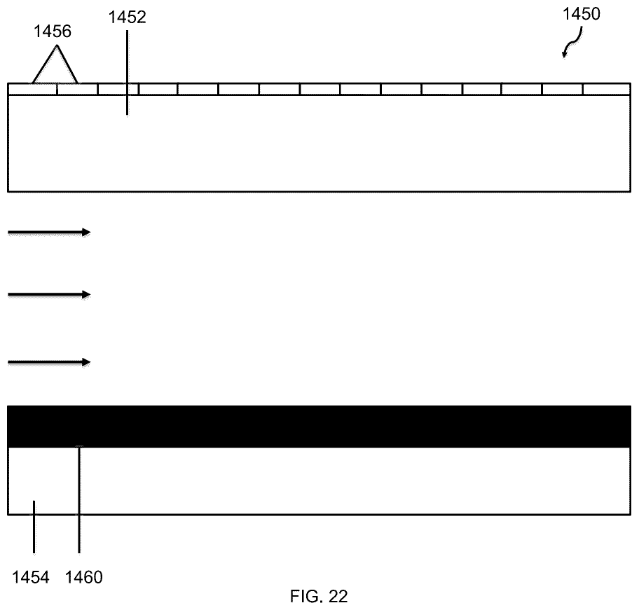

FIG. 22 illustrates a side-view of an example linear reactor 1450 configured for ion applications, such as ion etching, PVD, and PECVD. The example linear reactor 1450 may be substantially analogous to the example linear reactor 1300 in that it includes a top plate module 1452, a bottom plate module 1454, and a substrate 1460 placed therein. Furthermore, FIG. 22 illustrates fluid flow through the reaction chamber across an exposed surface of the substrate 1460. The example linear reactor 1450 may further include means for emitting high-frequency radiation 1456. The radiation created by 1456 is emitted into the reaction chamber to create ions from a fluid delivered into the reaction chamber, for example a plasma. The plate modules (1452, 1454) may be further equipped with cooling capabilities, such that they create a cold wall, to aid in the process. The generation of ions by the high-frequency radiation field may be then accelerated to the surface of the substrate 1460 by a perpendicular electric field, thus facilitating ion etching, target bombardment (PVD, or ion manipulation (PECVD) for chemical processing onto the substrate 1460.

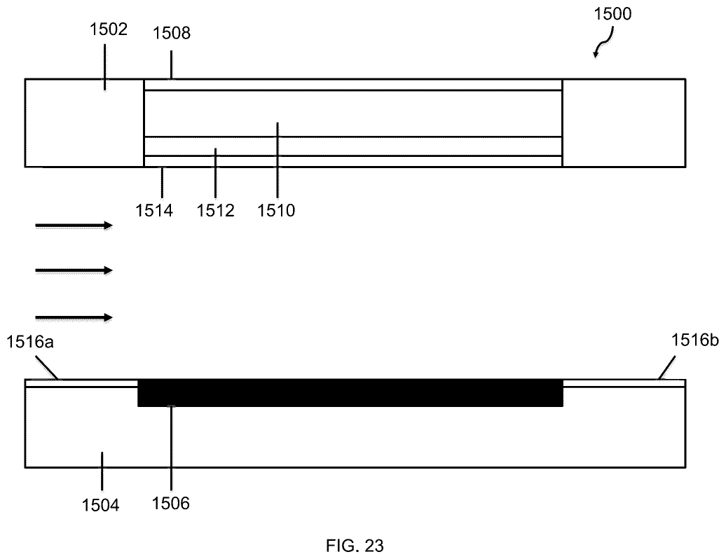

FIG. 23 illustrates a side-view of an example linear reactor 1500 configured for electroplating. The example linear reactor 1500 may be substantially analogous to the example linear reactor 1300 in that it includes a top plate module 1502, a bottom plate module 1504, and a substrate 1506 placed therein. Furthermore, FIG. 23 illustrates a flow of fluid through the reaction chamber across an exposed surface of the substrate 1506. The example linear reactor 1500 may further include an anode 1508, an anolyte solution 1510, a porous rigid support 1512, a membrane 1514, and a cathode contact point (1516a, 1516b). In this example configuration, the fluid may be a catholyte solution. The top plate module 1502 may be configured to provide a negative charge to the anode 1508 causing components of the anolyte solution to dissolve. Thus, establishing an electrolytic cell within the linear reactor 1500. Once dissolved the components of the anolyte solution may migrate through the porous rigid support 1512 and membrane 1514 towards the substrate 1506. Because the substrate 1506 is provided with a charge from the cathode contact points (1516a, 1516b), the dissolved anolyte components may be discharged at the substrate 1506. Thus, facilitating deposition onto the surface of the substrate 1506.

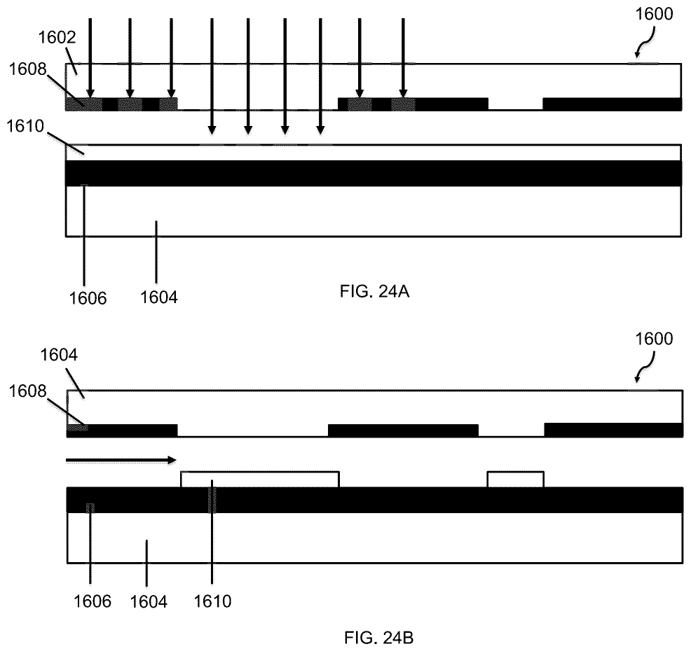

FIGS. 24A and 24B illustrate a side-view of an example linear reactor 1600 configured for photolithographic patterning. The example linear reactor 1600 may be substantially analogous to the example linear reactor 1300 in that it includes a top plate module 1602, a bottom plate module 1604, and a substrate 1606 placed therein. Furthermore, FIG. 24A illustrates Ultraviolet (UV) radiation exposure onto the substrate 1606 while FIG. 24B illustrates fluid flow through the reaction chamber across an exposed surface of the substrate 1606. The example linear reactor 1600 may further include chrome deposits 1608 within the top plate module 1602, and a film 1610. In one embodiment, the chrome deposits 1608 are molybdenum disilicide (MoSi2) deposits. The top plate module 1602 may be configured with chrome deposits 1608 positioned above locations of the film 1610 desired to be removed. UV light is then emitted through the top plate module 1602 reacting with the film on locations not below the chrome deposits 1608. The positions of the film 1610 receiving UV radiation are treated while the remaining positions are not. As illustrated in FIG. 24B, following UV treatment, a fluid (e.g., a solvent) is passed over the film 1610 and substrate 1606, dissolving and removing the untreated film positions. Thus, facilitating photolithographic patterning onto the surface of the substrate 1606.

The linear reactor framework may be further adapted to support solid film material staging. In some embodiments, the solid film staging may be effectuated by a reel-to-reel processing configuration for flexible film materials. Many sheet materials can be used as continuous or pulsed feed for direct chemical processing or as solid material reactants on another substrate. This feature can be used in applications like PVD, CVD, and wet processing. In the case of PVD the material could be used as a target for physical vapor generation. In CVD the material can be used as a reactant in the chemical process. The material can also be utilized as a catalyst to enhance chemical desired chemical reactions. In wet process, the material can be dissolved in a solvent for later deposition/transfer onto a substrate.

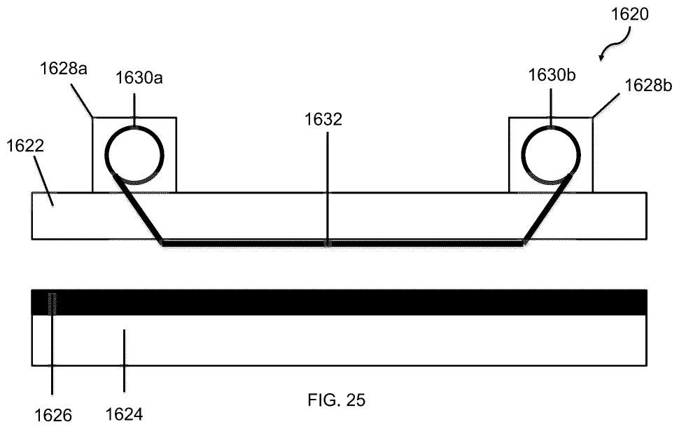

FIG. 25 illustrates a side-view of an example linear reactor 1620 configured for reel-to-reel processing of flexible film materials. The example linear reactor 1620 may be substantially analogous to the example linear reactor 1300 in that it includes a top plate module 1622, a bottom plate module 1624, and a substrate 1626 placed therein. Furthermore, FIG. 25 illustrates a first roll stack 1628a with an accompanying roll of flexible film 1630a contained therein and a second roll stack 1628b with an accompanying roll of flexible film 1630b contained therein. The roll stacks (1628a, 1628b) and associated rolls of flexible films (1630a, 1630b) may be configured to introduce a flexible film 1632 into the reaction chamber (i.e., between the first plate 1622 and second plate 1624). The flexible film 1632 may be a continuation of the roll of flexible films 1630a, 1630b, such that the flexible film 1632 may be rolled out from the first roll of flexible film 1630 and rolled into the second roll of flexible film. This may be facilitated by the roll stacks 1628a, 1628b, which include means to dispense the flexible film 1632 into and out of the reaction chamber. For example, the roll stacks 1628a, 1628b may include a mechanical spindle coupled to a motor operable to turn the spindle (either that of the first roll stack 1628a, second roll stack 1628b, and/or both) resulting in dispensing of the flexible film 1632. The roll stacks 1628a, 1628b and rolls of flexible film 1630a, 1630b may be a component to substrate handling modules or alteration modules, such as substrate handling module 1004a, 1004b and alteration module 1006a, 1006b of FIG. 13. Additionally, the roll stacks 1632a, 1632b and rolls of flexible film 1630a, 1630b may be a component to a top plate module 1008a or bottom plate module 1008b of FIG. 13. The example linear reactor 1620 of FIG. 25 may be used in this way to effectuate PVD, CVD, or wet processing. In the case of PVD the flexible material 1632 may be used as a target for physical vapor generation. In CVD the flexible material 1632 may be used as a reactant in the chemical process. The flexible material 1632 may also be utilized as a catalyst to enhance chemical desired chemical reactions. In wet process, the flexible material 1632 may be dissolved in a solvent for later deposition/transfer onto a substrate, such as substrate 1626.

While the example linear reactor 1620 illustrates the flexible material 1632 as being positioned substantially at a top portion of the reaction chamber and pressed against the top plate module 1622, the example linear reactor 1620 may be configured such that the flexible material 1632 is pressed against the substrate 1626. Additionally, the example linear reactor 1620 may be configured such that the flexible material 1632 is suspended in substantially the middle or at a lower end of the reaction chamber.

In some embodiments, solid film material staging may be effectuated by mechanical press to bond the solid film to a substrate. For example, a dry photo resistant film may be mechanically pressed and bonded to a substate.

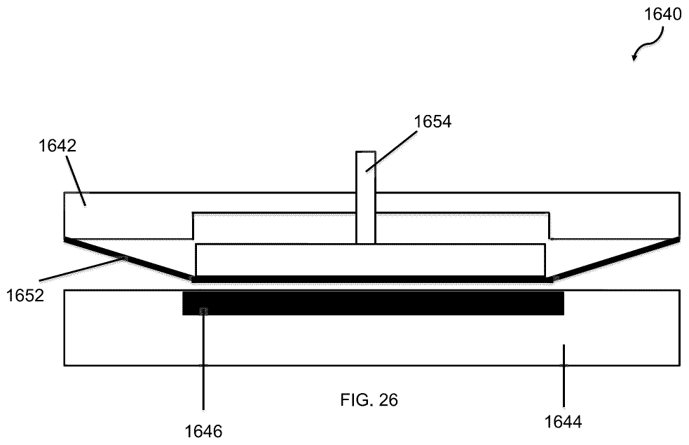

FIG. 26 illustrates a side view of an example linear reactor 1640 configured for mechanical pressing of solid films onto substrates. The example linear reactor 1640 may be substantially analogous to the example linear reactor 1300 in that it includes a top plate module 1642, a bottom plate module 1644, and a substrate 1646 placed therein. Furthermore, FIG. 26 illustrates a top plate module 1642 equipped with a press 1654 configured to press a solid film 1652 onto the substrate 1646, such that the solid film 1652 is adhered to the substrate 1646. For example, the solid film 1652 may be a dry photoresist that is applied to the substrate 1646 to create a resistant layer on a top surface of the substrate 1646. The press 1654 may be a component to substrate handling modules or alteration modules, such as substrate handling module 1004a, 1004b and alteration module 1006a, 1006b of FIG. 13. Additionally, the press 1654 may be a component to a top plate module 1008a or bottom plate module 1008b of FIG. 13. The example linear reactor 1640 of FIG. 26 may employ the roll stacks (1628a, 1628b) and associated rolls of flexible films (1630a, 1630b) of example linear reactor 1620 to feed the solid film 1652 into and out of the reaction chamber prior to or following pressing of the solid film 1652 by the press 1654.

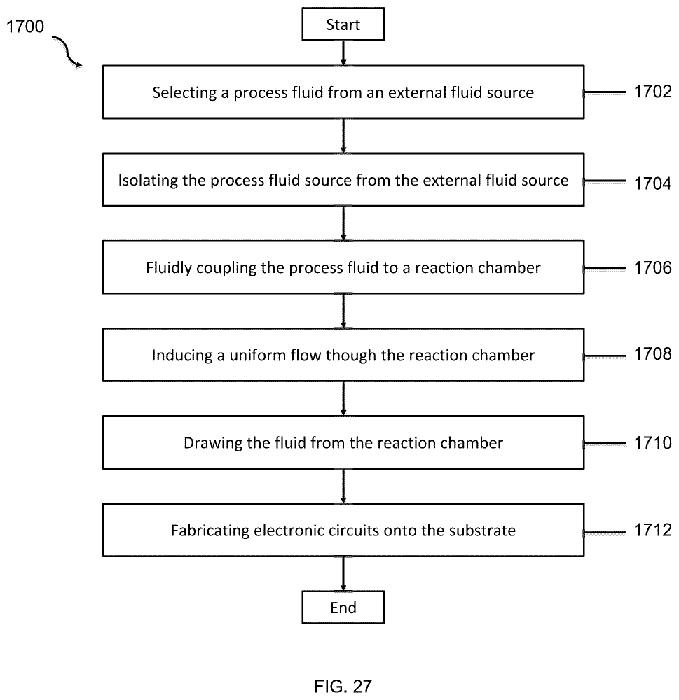

FIG. 27 illustrates a flow diagram of a method 1700 of processing a substrate. At step 1702, a process fluid is selected and introduced from an external fluid source. The process fluid may be selected and drawn into a first hydraulic volume of a first hydraulic device. For example, and with reference to FIG. 1, the process fluid may be drawn into the fluid volume 114a by piston 116a. However, any fluid management system, device, or component thereof, may be utilized to induce a process fluid into the linear reactor system. The process fluid may be drawn to the fluid volume utilizing the fluid delivery system 600 of FIG. 7, such that a variety of process fluids (610, 612, 614, 616, 618, 622, 624, 626) may be drawn as desired.

At step 1704, the process fluid may be isolated from the external fluid source. For example, and with reference to FIG. 9, the external fluid may be isolated from its source utilizing the isolation valve 821. Additionally, and with reference to FIGS. 6A-6D, other fluid management systems may be used.

At step 1706, the fluid may be coupled to the reaction chamber. For example, and with reference to FIG. 1, the coupling may occur between the fluid volume 114a and the reaction chamber of the linear reactor 102 by the gate load lock 120a. The gate load lock may be positioned between the reaction chamber and a fluid volume of a fluid management system and operable to prevent or permit fluid to enter said reaction chamber upon activation and deactivation.

At step 1708, a uniform flow of fluid is induced into the reaction chamber. For example, and with reference to FIG. 2A-2B, a fluid input module 110 may include a direct drive mechanism for inducing fluid into the reaction chamber 156. Due to the relatively low profile of the reaction chamber 156 and the placement of the substrate 150 in the depression in the second rigid plate 154, the uniformity of the surface diffusion is maintained, and the convention forces are controlled. This enables a uniform flow of fluid to be induced into the reaction chamber of the linear reactor.

At step 1710, fluid is drawn from the reaction chamber. For example, and with reference to FIG. 1, the process fluid may be drawn from the reaction chamber of the linear reactor 102 into the first fluid volume 114b by piston 116b. However, any fluid management system, or component thereof, may be utilized to draw a process fluid from the linear reactor system. The process fluid may be drawn to the fluid volume utilizing the fluid delivery system 600 of FIG. 7, such that a variety of process fluids (628, 630, 632, 634, 636, 638, 640, 642) may be drawn as desired.

At step 1712, electronic circuits and components thereof may be fabricated onto the substrate. The linear reactor of the present invention is operable to maintain a uniform fluid flow throughout its reaction chamber. The linear reactor may be fluidly coupled to a fluid management system operable to establish the initial flow of fluid. The linear reactor may further be included in a linear reactor framework operable to accommodate modules to affect an environment of the reaction chamber and alter the properties of the fluid induced therein. Thus, the linear reactor framework may be configured to facilitate a wide variety of substrate processing and intermediate steps in order to fabricate semiconductors or other nanodevices. For example, and with reference to FIG. 18, the linear reactor 1300 may be configured for chemical free processing for surface treatment and photoresist removal. As another example, and with reference to FIGS. 19 and 20, the linear reactor 1350 may be configured for ALD. As another example, and with reference to FIG. 21, the linear reactor 1400 may be configured for ion plasma generation with applications in PECVD, PVD, and dry etching. As another example, and with reference to FIG. 22, the linear reactor 1450 may be configured for ion etching. As another example, and with reference to FIG. 23, the linear reactor 1500 may be configured for electroplating. As another example, and with reference to FIGS. 24A and 24B, the linear reactor 1600 may be configured for photolithographic patterning, PECVD, PVD, dry etching, or CMP.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

Although embodiments described herein are made with reference to example embodiments, it should be appreciated by those skilled in the art that various modifications are well within the scope of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

I claim:

1. A system for processing a substrate comprising:
a first plate defining a first surface;
a second plate positioned off-set and parallel to the first plate defining a second surface, wherein the second plate and/or the first plate is configured to receive the substrate and arrange a surface of the substrate parallel to and in-plane with the first surface or the second surface;
a reaction chamber formed between the first surface and the second surface with the second surface of the second plate within the reaction chamber;
a first fluid management device, positioned at a first end of the first plate, in fluid communication with the reaction chamber, and configured to introduce fluid into the reaction chamber;
a second fluid management device, positioned at a second end of the first plate, in fluid communication with the reaction chamber, and configured to receive and/or draw fluid from the reaction chamber; and
wherein the system is configured to fabricate electronic circuits onto the substrate by passing fluid over the substrate from the first hydraulic device to the second hydraulic device.

2. The system of claim 1, wherein
the first fluid management device comprises first hydraulic device including a first piston positioned within a first hydraulic volume,
the system further includes
a first isolation valve operable to facilitate fluid communication between the first hydraulic device and an external fluid source, and
a first gate load lock positioned between and separating the first hydraulic volume and the reaction chamber, and
the first piston is configured to
draw the fluid from the external fluid source into the first hydraulic volume, and
upon closing of the first isolation valve and opening of the first gate load lock, induce a flow of the fluid into the reaction chamber.

3. The system of claim 2, wherein
the external fluid source comprises a plurality of individual fluids, and
the first isolation valve is a component of a manifold that selectively controls the fluid coupling of each fluid of the plurality of individual fluids to the first hydraulic device.

4. The system of claim 2, wherein
the first hydraulic volume includes a volume having a width substantially equivalent to a width of an internal volume of the reaction chamber, and
the first piston is configured to induce a flow of the fluid into the reaction chamber such that a velocity of the fluid increases through the reaction chamber while the mass flow rate remains constant.

5. The system of claim 4, wherein a ratio of the cross-sectional area of the first hydraulic volume to the cross-sectional area of the reaction chamber is at least 40:1.

6. The system of claim 1, wherein the reaction chamber is enclosed by an edge seal connecting the first plate to the second plate to define a linear flow path for the fluid through the reaction chamber along the first surface and second surface.

7. The system of claim 1, wherein the first plate comprises
an inlet extending therethrough and fluidly coupling the hydraulic device and a first end of the reaction chamber, and
an outlet extending therethrough and fluidly coupling the second hydraulic device and a second end of the reaction chamber.

8. The system of claim 7, wherein the surface of the substrate is arranged between the first and second ends of the reaction chamber.

9. The system of claim 1, wherein
the first plate and/or the second plate includes a removable section including a depression configured to house the substrate such that the substrate is flush with a top surface of the second plate, and
the removable section is configured to selectively place the substrate within the reaction chamber.

10. The system of claim 1, wherein the first plate and/or the second plate include at least one electrode mounted to an interior surface of the first plate and/or second plate and wherein the at least one liner is operable to pass a current through an environment of the reaction chamber.

11. The system of claim 1, wherein the first plate and/or the second plate include at least one layer positioned within or integrally formed to the first plate and/or second plate and wherein the at least one layer is operable to heat and/or cool an environment of the reaction chamber.

12. The system of claim 1, wherein the system is operable to produce a uniform fluid velocity profile within the reaction chamber and across the surface of the substrate within the reaction chamber.

13. The system of claim 1, wherein the substrate is a silicon wafer.

14. The system of claim 1, wherein fabricating electronic circuits onto the substrate comprises one or more of lithography, photoresist coating, Chemical mechanical Polishing (CMP), Physical Vapor Deposition (PVD), Chemical Vapor Deposition (CVD), diffusion, ion implantation, dry etching, stripping and/or wet processing.

15. A system for processing a substrate comprising:
a reactor module configured to induce a uniform flow of a process fluid across a surface of a substrate held within a linear reaction chamber;
a fluid input module fluidly coupled with the reactor module and configured to deliver a flow of the process fluid to the linear reaction chamber;
a fluid output module fluidly coupled with the reactor module and configured to receive and/or draw fluid from the linear reaction chamber;
at least one support module thermally and fluidly coupled with the reactor module and configured to control a temperature of the reaction chamber, a pressure of the reaction chamber, and/or a flow rate of the fluid; and
at least one side module electrically coupled with the reactor module and configured to provide an electric current to the fluid and/or an electric field to the reaction chamber,
wherein the reactor module, the fluid input module, the fluid output module, the at least one support module, and the at least one side module cooperate to fabricate electronic circuits onto the substrate within the linear reaction chamber.

16. The system of claim 15, wherein the reactor module, the fluid input module, the fluid output module, and the at least one support module define a modular framework whereby the modular framework is configured to facilitate removable attachment of the fluid input module, the fluid output module, the at least one support module, and/or the at least one side module to and from the reactor module.

17. The system of claim 15, wherein
the system further comprises at least one substrate handling module configured to introduce a substrate to the reaction chamber, and
the modular framework includes the at least one substrate handling module.

18. A method for processing a substrate comprising:
selecting a process fluid from an external fluid source;
isolating the process fluid from the external fluid source;
fluidly coupling the process fluid to a reaction chamber;
inducing a uniform flow of process fluid through the reaction chamber by generating pressure at an inlet of the reaction chamber causing flow of the process fluid into the reaction chamber;
drawing the fluid from the reaction chamber by generating pressure at an outlet of the reaction chamber opposite the inlet; and
fabricating electronic circuits onto the substrate by passing the uniform flow of process fluid over the substrate positioned within the reaction chamber.

19. The method of claim 18, further comprising applying an electric current to the uniform flow of process fluid by at least one electrode electrically coupled with the reaction chamber.

20. The method of claim 20, wherein the fabricating electronic circuits onto the substrate comprises one or more of lithography, photoresist coating, Chemical mechanical Polishing (CMP), Physical Vapor Deposition (PVD), Chemical Vapor Deposition (CVD), diffusion, ion implantation, dry etching, stripping, and/or wet processing.
